(19) United States
(12) Patent Application Publication
(10) Pub. No.: US 2024/0170585 A1
(43) Pub. Date: May 23, 2024

(54) APPARATUS AND METHOD FOR SOLAR PANEL WITH INTEGRATED WIRE MANAGEMENT

(71) Applicant: Lumeta, LLC, Costa Mesa, CA (US)

(72) Inventors: ERWANG MAO, Palo Alto, CA (US); BRIAN JOSEPH FLAHERTY, Alamo, CA (US); CHAD MEDCROFT, San Rafael, CA (US); MICHAEL JOHN NICHOLS, Emeryville, CA (US); TIMOTHY MICHAEL DAVEY, Costa Mesa, CA (US)

(21) Appl. No.: 18/373,552

(22) Filed: Sep. 27, 2023

Related U.S. Application Data
(63) Continuation of application No. 16/982,446, filed on Sep. 18, 2020, now abandoned.
(60) Provisional application No. 62/645,026, filed on Mar. 19, 2018.

(51) Int. Cl. H01L 31/02; H02S 20/24; H02S 30/10; H02S 40/34; H02S 40/36

(52) U.S. Cl. CPC H01L 31/02008; H02S 20/24; H02S 30/10; H02S 40/34; H02S 40/36

(57) ABSTRACT

A photovoltaic module generates electrical power when installed on a roof. The module is constructed as a laminated sandwich having a transparent protective upper layer adhered to a photovoltaic layer. The photovoltaic layer is adhered to the top of a rigid layer, preferably formed from a fiber reinforced plastic. A wire support tray assembly is affixed to an edge of the photovoltaic module, the wire support tray assembly includes a base portion and a cover portion. The base portion has at least one base portion flange configured to lock with least one corresponding cover portion flange. The base portion has a longitudinally-extending slot configured to couple with the edge of the photovoltaic module. Preferably the wire tray assembly holds the module wiring and occludes it from view. Preferably, the cover portion is concave to shelter the wiring from inclement weather.

This application is a continuation application of U.S. patent application Ser. No. 16/982,446 filed on Sep. 18, 2020, which is a National Stage entry filed under 35 U.S.C § 371 of International Application No. PCT/US2019/022899, with an International Filing date of Mar. 19, 2019, which claims priority to U.S. Provisional Patent Application No. 62/645,026, filed Mar. 19, 2018, the contents of which are incorporated herein by reference.

### BACKGROUND OF THE INVENTION

### 1. Field of the Invention

The present invention relates to solar panels/modules for generating electrical energy, and more particularly to photovoltaic panels/modules with integrated wire management structures, preferably on-board. This application is an improvement of U.S. patent application Ser. No. 14/732,010, filed Jun. 15, 2015, the entire contents of which are incorporated herein by reference.

### 2. Description of the Related Art

Conventional photovoltaic modules for generating electrical power for residences and businesses are often flat and are placed on a portion of a roof that is exposed to the sun. Historically, such modules were placed on structures erected on the roof to support and protect the modules. More recently, photovoltaic modules have become available that can be mounted directly on a flat or tilted roof. See, for example, US Patent Application Publication No. 2005/0178428 A1 to Laaly et al., (the entire contents of which are incorporated herein by reference), which discloses a module that incorporates a roofing membrane into the module structure. The module is intended to be installed on a new roof or replacement roof with the membrane providing moisture protection for the underlying structure as well as providing electrical power.

See also U.S. Pat. Nos. 7,531,740 and 7,557,291 both to Flaherty, et al., the entire contents of both of which are incorporated herein by reference. These patents disclose such photovoltaic modules for roof-top installation.

A problem with above mentioned direct roof top attached crystalline silicon photovoltaic cell based solar modules is their installation tends to take a great deal of time in laying the panels out and then electrically connecting plural panels together to form the desired array. During installation, a part of or all of the wiring is left, and is often is exposed to the elements. Some solutions have been proposed in which plug-and-play type side connectors have been added to quickly plug together plural solar modules. See, for example, U.S. Pat. Nos.: 7,713,089; 7,819,114; 8,455,752; and 8,922,972; and also USPPNs 2008/0149170; 2013/0263910; and 2014/0090694; the contents of each of which are incorporated herein by reference. However, these proposed solutions still require a skilled worker to run the different required wirings from module to module, or from groups of modules to groups of modules. Thus, what is needed is a solar panel/module system that is quick and easy to install, and provided superior electrical connections.

### SUMMARY OF THE INVENTION

The photovoltaic module described herein and illustrated in the attached drawings enables electricity-generating solar modules to be installed quickly and with reliable electrical connections that offer additional protection to the module cables.

In accordance with one aspect according to the present invention, a photovoltaic module has an upper transparent protective layer, and a photovoltaic layer positioned beneath the upper transparent protective layer. The photovoltaic layer includes a plurality of electrically interconnected photovoltaic cells disposed in an array. A semi-rigid substrate layer is positioned beneath the photovoltaic layer. A wire support tray assembly is affixed to an edge of the photovoltaic module; the wire support tray assembly comprising a base portion and a cover portion. The base portion has at least one base flange configured to lock with at least one corresponding cover portion flange. The base portion has a longitudinally-extending slot configured to couple with the edge of the photovoltaic module.

In accordance with another aspect according to the present invention, a photovoltaic module has a rectilinear panel having a surface with a plurality of photovoltaic cells disposed thereon in an array. A wire tray assembly is disposed along at least one edge of the photovoltaic module; the wire tray assembly including a base portion and a cover portion. The cover portion has structure configured to removably couple the cover portion to the base portion. Preferably, the wire tray assembly is made of a flexible plastic material. The cover portion preferably has a substantially concave-shaped cross section. At least one joint cover portion is configured to cover adjacent base portions disposed at a junction of said adjacent base portions.

In accordance with a further aspect according to the present invention, a photovoltaic module has a rectilinear panel having a plurality of photovoltaic cells disposed thereon in an array. All four edges of the panel are preferably tapered edges. At least one panel edge has a wiring tray assembly having (i) a base portion, and (ii) a cover portion. The cover portion is removably coupled to the base portion and has a substantially concave cross section configured to deflect water from entering the wiring tray assembly.

In accordance with yet another aspect according to the present invention, a method of assembling a photovoltaic module includes, in any order: (i) providing a rectilinear photovoltaic panel having a plurality of cells disposed thereon; (ii) coupling a wire tray base portion to an edge of the photovoltaic module; (iii) inserting photovoltaic module wiring into the wire tray base portion; and (iv) coupling a wire tray cover portion to the wire tray base portion so as to cover and protect (and occlude) the photovoltaic module wiring.

### BRIEF DESCRIPTION OF THE DRAWINGS

Certain aspects in accordance with embodiments of the present invention are described below in connection with the accompanying drawing figures in which:

FIGS. 1a and 1b illustrate a perspective view of a first embodiment of a laminated photovoltaic module and rear view of the module, respectively, according to an embodiment of the present invention.

FIG. 2 illustrates a top view of the photovoltaic module of FIG. 1a with junction box showing conductors;

FIG. 3 illustrates a perspective view of the photovoltaic module of FIG. 1a, showing the wiring support structure according to a preferred embodiment;

FIG. 4 illustrates another perspective view of the photovoltaic module of FIG. 3;

FIG. 5 illustrates a top plan view of the FIG. 4 embodiment;

FIG. 6 illustrates another top plan view of the FIG. 4 embodiment;

FIGS. 7a, 7b, 7c, and 7d illustrate close-up perspective views of wiring support clips usable in the photovoltaic module of FIG. 1a;

FIGS. 8a and 8b illustrate close-up perspective view of wiring support clips usable in the photovoltaic module of FIG. 1a; and

FIGS. 9a and 9b illustrate perspective and cross-sectional views of an embodiment including wire trays.

FIG. 10a is a front view of the solar module with integrated wire management, including a wire tray cover attached. FIG. 10b is a front view of the solar module with integrated wire management, illustrating the wire tray cover removed. FIG. 10c is a rear view of the solar module with integrated wire management, showing the wire tray cover attached. FIG. 10d is a side view of the solar module with integrated wire management, showing the wire tray cover attached.

FIG. 11 is a close-up cross-sectional view of the FIG. 10b module, with the cover attached.

FIG. 12 is a perspective, partial view of the wire tray cover.

FIG. 13 is a perspective view of the wire tray with a cut out for the junction box.

FIG. 14a is a cross-sectional view of an embodiment where the wire tray cover is hinged, showing the cover open. FIG. 14b is a cross-sectional view of an embodiment where the wire tray cover is hinged, showing the cover closed and locked.

FIGS. 15a and 15b are top views of a solar module illustrating presently preferred embodiments. FIGS. 15c and 15d are side views of the corresponding preferred embodiments

FIGS. 16a, and 16b are side views of preferred embodiments showing the wire tray and cover. These images highlight the winged feature of the wire tray which has been designed to retain the wires, making it easier to connect and manage wires between modules.

FIGS. 17a, 17b, 17c, and 17d, are side views showing the operation of preferred embodiments.

FIGS. 18a, 18b, and 18c are perspective views showing end cap structure, according to the preferred embodiment.

FIGS. 19a and 19b are side views showing a preferred embodiment.

FIGS. 20a, 20b, and 20c are perspective views showing end cap structure, according to the preferred embodiment.

FIG. 21 is a perspective view of a home run wire tray assembly base according to a preferred embodiment.

FIG. 22 is a perspective view of a home run wire tray according to a preferred embodiment.

FIG. 23 is a perspective view of a home run wire tray cover according to a preferred embodiment.

FIGS. 24a, 24b, 24c, and 24d are side views of a home run wire tray assembly according to a preferred embodiment.

FIG. 25 is a top view of a home run wire tray assembly with solar module array, according to a preferred embodiment.

FIGS. 26a, 26b, 26c, 26d, 26e, and 26f are perspective views of home run wire tray assembly covers and joints.

FIGS. 27a and 27b are perspective views of the home run wire tray assembly showing the end cap structure.

FIGS. 28a, 28b, 28c, and 28d are perspective views of the home run cover components combining the “L” joint with transition portions.

FIGS. 29a and 29b are perspective views of the home run cover components combining the “T” joint with transition portions.

FIG. 30a is a section view of a solar module embodiment with integrated wire tray showing 3 mounting holes for easy module handling. FIG. 30b is a perspective view of the base of FIG. 30a showing the mounting holes in greater detail.

FIGS. 31a and 31 b depict an embodiment of the PV module with an aluminum label over the junction box.

FIGS. 32a, 32b, and 32c show an alternative embodiment featuring an elongated junction box and easy-connect electrical cables.

FIGS. 33a, 33b, 33c, and 33d show an alternative embodiment of adhesion pad placement on the back side of the PV module, together with a protective covering over the adhesion pads.

FIGS. 34a, 34b, 34c, 34d, and 34e show an alternative embodiment showing a smaller footprint tray and cover, together with a symmetrical cover.

FIGS. 35a, 35b, 35c, 35d, and 35e show another alternative embodiment showing a smaller footprint tray and cover, with a rounder profile.

FIGS. 36a, 36b, and 36c show a further alternative embodiment showing a bent edge portion on the cover for easy removal.

FIGS. 37a and 37b show end caps for the FIGS. 34a and 35a embodiments.

### DETAILED DESCRIPTION OF THE PREFERRED EMBODIMENTS

Briefly, the present integrated wire/cable management structures for both residential and commercial photovoltaic (“PV”) modules are designed to: (i) keep module interconnection wiring, jumpers, and home run cables off roof surfaces, (ii) minimize system install time and wire tray usage, (iii) minimize installation errors in the field, (iv) enhance protection from weather and solar related degradation, and (v) assist with safely hoisting the module to the roof. The low profile (height) of the wire clips does not substantially increase wind resistance of the installed photovoltaic systems and also enhances the aesthetics thereof. As wire management clips are exposed to direct sun light, stainless steel clips are preferred to minimize the impact of UV degradation. UV-resistant polymer materials can also be used for the wire clips. “Integrated” means where all parts of the wire assembly described herein are configured to fit together into a preferably single coordinated structure, comprising base, cover, tray, joints, etc. Preferably the integrated structure is designed to be attached to the photovoltaic module, and thus disposed “on-board” the module.

PV wiring requirements for residential roof top installations should meet the National Electrical Code (“NEC”) latest revision, currently 2014 and 2017 in some jurisdictions. Many Authorities Having Jurisdiction (“AHJs”), such as state, county, and municipal governing bodies follow the NEC code. But, some local codes could be more stringent. For possible PV commercial and industrial uses, PV module interconnection requirements are typically defined by the AHJ for: AC modules; DC modules with module level power control; DC modules with string power control, i.e. with line inverters; home run cable requirements, etc.

Preferably, the PV installation should involve no cable (or any other) penetration through roof deck. Cables should run on the roof only. With the present invention, those cables will be kept up off of the roof and substantially co-planar with the PV panels. Preferably, Underground Service Entrance (“USE”)-2-rated or Underwriters Labotratory (“UL”) 4703-rated or equivalent AC/DC PV cables are used, for direct, exposed to sun irradiation applications. Cables and connectors should not be in direct contact with the roof. This is achieved in the present invention where the co-planar wiring support clips (or trays) hold the cables above the roof surface. Cable connectors are preferably interlocked, and the connector interlocking preferably is by hand-only. Disconnecting is preferably achieved with tools per NEC 2008 and 2011. Interconnection cables are preferably fixed within 300 mm from a junction box, as is provided with the clips according to the present invention. Cables should be fixed in place every 1.4 m of run-length; again, easily achieved with the clips according to the present invention, which fix the cables at approximately every 6-46 inches, preferrably about 12 inches.

The cabling/wiring that runs from the coupled-together plural PV panels to an electrical/mechanical collection device is termed the home run cabling. Home run cable should preferably be kept off roof, which is accomplished according to the present invention, and may be routed through one or more electrical conduits. The clips according to the present invention are preferably sized to accommodate one or a plurality of home run cables. Usable conduit types include Rigid Metal Conduit (“RMC”) and/or Intermediate Metal Conduit (“IMC”). UV resistant, liquid-proof liquid tight flexible plastic conduit may also be used. Cables in conduits should be water resistant. Conduit dimensions may be determined by fill-factor and cable cross section areas. Steel junction boxes or polymer junction box with knock-outs can be used for interconnecting cables and/or wires to home run cables.

As will be described in greater detail below, preferably, one or two wire clips may be located adjacent to the junction box, and/or the DC power optimizer, and/or the micro inverter, and/or packet energy transfer (PET) module, mounted on the PV module. Additional clips may be added to a module for jumpers and home run cable management. The locations of the additional clips may be on the same side of the junction box and/or adjacent to the junction box side and/or opposite to the junction box side, depending on any specific application. A number of, 0 to (but not limited to) 20, additional clips can be added to a module based on any specific application. The original and/or additional clips may be added at the factory, on the work-site, or even on the roof.

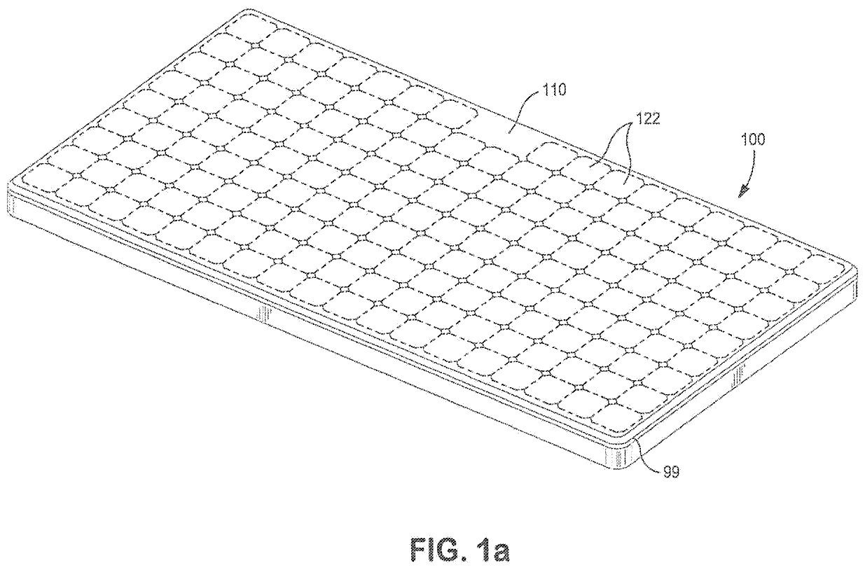

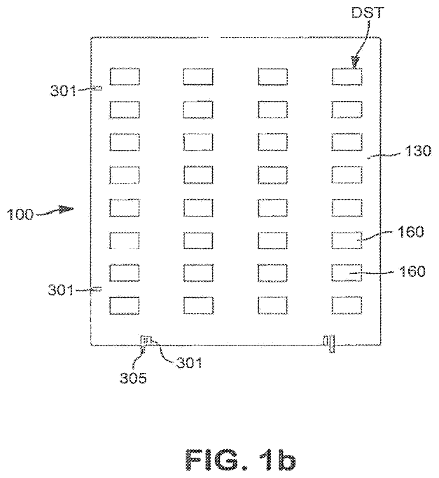

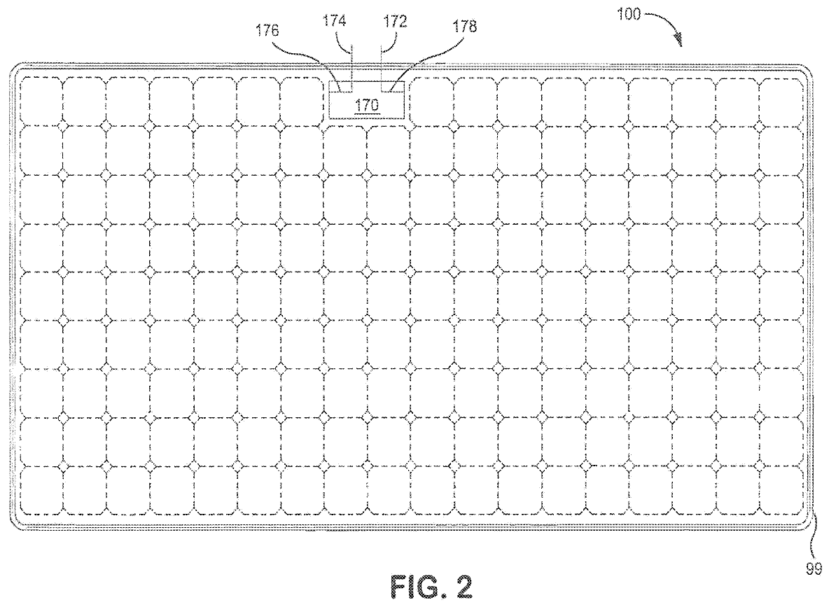

As illustrated in FIGS. 1a, 2, 3, 4, and 5, of co-pending U.S. application Ser. No. 14/454,226, filed Aug. 7, 2014 (the contents of which are incorporated herein by reference), and with reference to FIGS. 1a and 2 of the subject application, a laminated photovoltaic module 100 is preferably configured as a generally rectangular module, which is sized and shaped in accordance with the sizes and shapes of conventional building materials, such as a 4×8 foot module. Thus, the module 100 can be handled by a construction crew without requiring any special material handling equipment. Of course, the module 100 may be any convenient size (4×8, 4×6, 4×4, 3×3, 3×2, 2×2, 2×1, 1×1, etc.), and shape (square, round, triangular, trapezoidal, etc.) useful in the construction industry, and with either rounded corners or substantially right angle corners.

The module 100 is preferably assembled in a factory or other suitable environment so that the module 100 is complete and ready to install on a substantially flat roof (which may be horizontal or tilted), or sloped shingle roofs, such as, but not limited to, asphalt, laminated, wood, slate, concrete, or other location having adequate exposure to the sun. In one preferred embodiment, as shown in FIGS. 1a and 2, 3, the module 100 has dimensions of approximately 99-101 centimeters (˜39-40 inches) by 199 centimeters (˜78 inches) and has a thickness of approximately 0.5 centimeter (0.2 inch). In another preferred embodiment, the module 100 has dimensions of approximately 101 centimeters (˜40 inches) by 101 centimeters (˜40 inches) and has a thickness of approximately 0.3 centimeter (⅛ inch) when installed. In fact, the thickness of the module may be the same as (or thinner than) the thickness of the laminated roofing shingle. Thus, the module 100 does not add significant height to a roof structure and will not block water flow on sloped roofs. In yet another embodiment, the module 100 has dimensions of approximately 99-101 centimeters (˜39-40 inches) by 239 centimeters (˜94 inches) and has a thickness of approximately 0.5 centimeter (0.2 inch). In a particularly preferred embodiment, the module has dimensions of 99 cm×167.5 cm×0.5 cm.

As shown in FIG. 1a, the module 100 preferably has a transparent upper protective layer 110 that faces upward and is exposed to the sun. A middle layer is preferably positioned beneath the upper protective layer 110. The middle layer comprises a plurality of photovoltaic cells 122 electrically interconnected to form a photovoltaic array. The middle layer preferably rests on a rigid lower substrate. The middle layer is preferably secured to the rigid lower layer by a lower adhesive layer. The middle layer is preferably secured to the upper protective layer 110 by an upper adhesive layer. The middle layer is thus encapsulated between the lower adhesive layer and the upper adhesive layer.

The upper protective layer 110 preferably provides impact protection as well as weather protection to the module 100. The upper protective layer 110 advantageously comprises of a transparent flexible polymer material, such as, but not limited to Ethylene tetrafluoroethylene (ETFE), a fluorine based co-polymer, which is formed into a film layer of suitable thickness (e.g., approximately 0.005-0.015 centimeter (0.002-0.006 inch)). Thus, the photovoltaic cells 122 in the middle layer are exposed to direct sunlight without being exposed to moisture and other climatic conditions and without being exposed to direct impact by feet, falling objects, and debris. Tempered glass or weather resistant polymer materials having a suitable thickness may also be used as the upper protective layer 110.

The rigid lower layer substrate preferably comprises fiber reinforced plastic (FRP). For example, the FRP layer advantageously comprises a polyester resin with embedded stranded glass fibers. Preferably the said FRP layer has a thickness of approximately 0.1 centimeter to 1 centimeter (0.079 inch-0.39 inch), and additionally, the said FRP lower surface can be either flat or with a defined pattern/rib. The lower layer of FRP thus provides an advantageous combination of rigidity, light weight, very low permeability, and flatness.

As shown in FIG. 2, the preferred embodiment provides that the photovoltaic cells 122 are electrically interconnected in a series-parallel configuration in a conventional manner to provide a suitable output voltage or a desired photovoltaic module form factor. For example, FIGS. 1a and 2 show a photovoltaic module suitable for flat roof application. Photovoltaic cells 122 are arranged in 6 rows of 12 cells each; however, one, two, or more cells may be omitted from at least one of the edge rows to provide room for positioning an electrical enclosure, such as, but not limited to junction box 170 (having a first weather-resistant electrical conductor 172 and a second weather-resistant electrical conductor 174), module power optimizer, micro inverter, and other useful electrical control and/or power-conditioning circuitry, as discussed above. The photovoltaic module 100 preferably includes two module output conductors 176, 178 (e.g., FIG. 2) that extend from the top surface of the middle layer in the area of the omitted photovoltaic cell(s). Each of the module output conductors 176, 178 is preferably connected to a respective one of the weather-resistant electrical conductors 172, 174 within the electrical enclosure 170 after the photovoltaic module 100 is laminated, as discussed below. In an alternative embodiment, the junction box may be mounted on the bottom surface of the solar panel, opposite the side on which the solar cells are mounted.

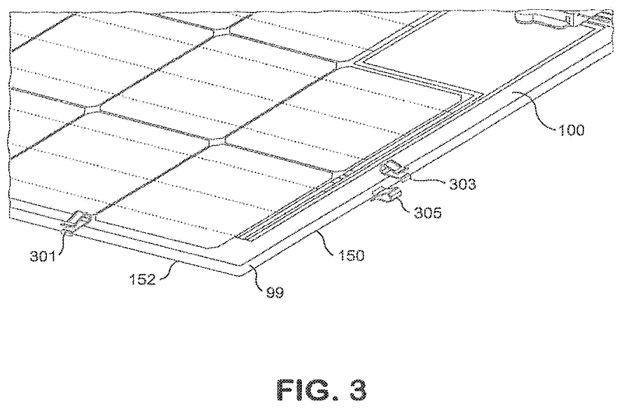

FIG. 3 is a close-up perspective view of the FIG. 1a embodiment, showing plural wiring support members 301, 303, and 305. In this embodiment, the wiring support members 301, 303, and 305 are stainless steel clips which are (preferably) permanently attached to the edges of the PV module via screw(s), rivet(s), glue(s), interference fit, hot-melt, tape(s) etc., or any combination of these. Preferably, the clips are installed on the sloped surfaces of the tapered edge 99. The clips may be installed in the factory either during or after manufacture of the PV module 100. Alternatively, the clips may be installed in the field, for example, with weather-proof adhesive tapes, foam tapes, two-sided tapes, hot melt, glue-gun, butyl tape, etc. The clips are sized and dimensioned so as to support one or more of (i) wire(s) and/or cable(s), (ii) conduit(s) which hold one or more wire(s) and/or (cables), and/or (iii) wiring tray(s) which hold one or more of (i) and/or (ii). As one example, plural clips 305 may hold a wire, or a homerun cable, or be configured to releasably (or permanently) couple with a corresponding receptacle(s) (or protrusion) in the side of a wire tray. Most preferably, each clip 305 is multi-modal, and can support one or more wires, and/or one or more cables, and/or one or more conduits, and be coupleable to corresponding structure on/in a wiring tray.

The clips 301, 303, and 305 are preferably disposed on at least two perpendicular edges of the PV module 100. In the most preferred embodiment, the clips are disposed along a front edge 150, a first side edge 152, and a second side edge (not shown). Of course, clips can be provided on all four edges. As can be seen in the drawings, the clips 301 and 303 are disposed so that the clip structure does not protrude substantially beyond the outer edge of the edges 150 and 152. As used herein, “does not protrude” encompasses insubstantial protrusions where the clip is affixed to the edges 150 and 152, as shown in the Figures. Thus, each of clips 301 and 303 has an opening which faces outward away from an interior of the PV module 100. These clips are useful for wiring one module to another, and their design keeps the wires/cables from overlying the photovoltaic cells. Clip 305, on the other hand, protrudes beyond an outer edge of the edge 150, and has an opening which faces inward toward an interior of the PV module 100. Clips 305 are useful for homerun wires/cables which carry the electricity to a roof junction box (not shown) where the power is collected and directed to an inverter and electrical panel.

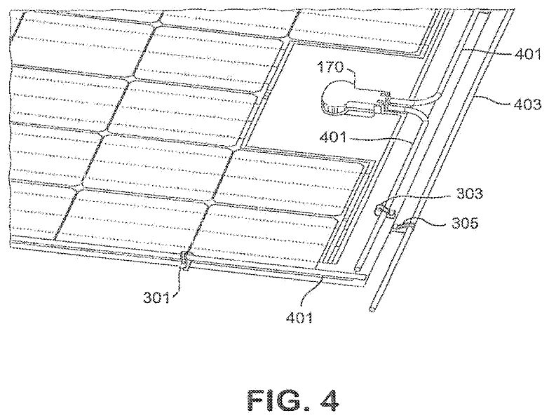

FIG. 4 shows the PV module 100 with wires/cables/conduits 401 which are held by clips 301 and 303; and wires/cables/conduits 40 which are held by one or more of clip 305, The wires 403 may comprise homerun cabling. Also shown in FIG. 4 is one or more electrical devices 170, which may comprise electrical circuitry (discussed above), which collects power from the solar cell (may condition it), and directs it off-board via wires 401. The device 170 may conveniently be disposed on an upper surface of the PV module 100 where one or more (preferably two) cells are missing from the array. Note that the clips are preferably designed so that the wires/cables may be easily inserted therein and/or removed therefrom. Note also that the device 170 is disposed between two rows of solar cells (running substantially horizontally in the Figure), but substantially in-line with the row of solar cells (running substantially vertically in the Figure).

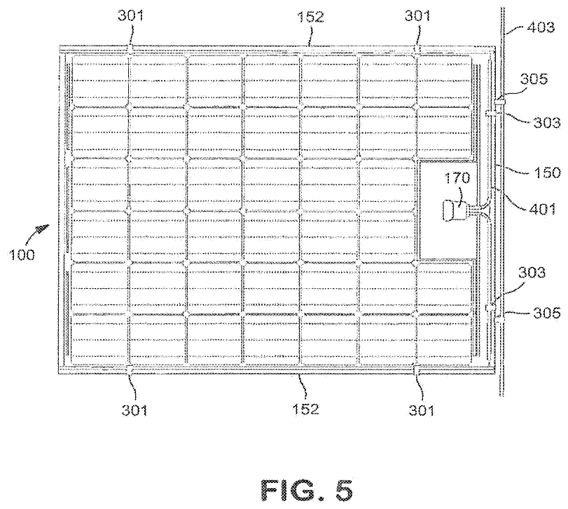

FIG. 5 is a top plan view of the FIG. 4 embodiment showing a substantially square PV module 100, with clips 301 on left and right side edges 152 of the module, and clips 303 and clips 305 on the front edge 150 thereof. Preferably, the edges 152 are perpendicular to the edge 150.

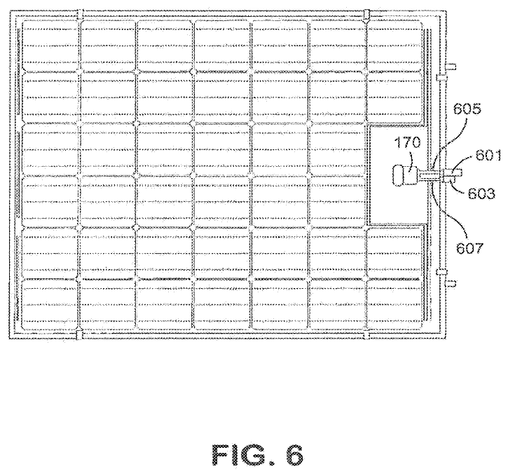

FIG. 6 is a top plan view of the FIG. 4 embodiment showing a preferred configuration in which the electrical device 170 is equipped with weather resistant plugs 601 and 603, each coupled to the device 170 with respective short, flexible, weather resistant cables 605 and 607. The plugs 601 and 603 can be removably (or permanently) coupled to corresponding plugs on wires/cables 401 and/or 403.

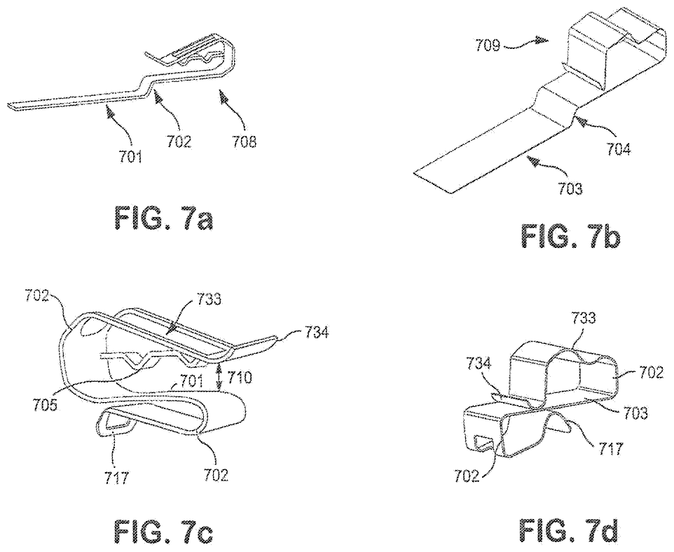

FIGS. 7a, 7b, 7c, and 7d are perspective views of various clips which may be used in accordance with the present invention for holding wires/cables, etc., as discussed above. The clips may be modified Heyco SunRunner clips (FIG. 7a), and SunRunner 2 clips (FIG. 7b), with dimensions based on cable diameters. These clips may be provided by Heyco Products, Inc., 1800 Industrial Way, Toms River, NJ 08755. Flat extensions, 701 and 703 may replace the SunRunner (FIG. 7c) and SunRunner 2 (FIG. 7d) clips' crimp structures, respectively. Each flat extension is preferably 1-1.5 inch long and with the same width and thickness to the SunRunner and SunRunner 2 clips. In one preferred embodiment, the flat portion is extended from the wire/cable clip portion. More preferably, a gradual bend 702 and 704, of 3-6 mm in height is inserted between the flat portion and the wire/cable clip portion, that substantially levels (makes horizontal) the wire/cable clip portion, 708 and 709, respectively to the top surface of the PV module.

The clips 301 and/or 305 preferably include an upper portion 733 which is biased in a direction substantially orthogonal to the plane of the upper surface of the PV module 100. This biasing acts to keep the wiring/cabling/conduits securely held within the clip. The upper portion 733 preferably includes an upwardly extending tang 734, which acts to guide wiring/cabling/conduits into the interior of the clip during installation. Note that the clip has an opening 710 which is preferably narrower than an interior thereof. In a preferred embodiment, the clip also includes an interior bias member 705, which acts to compress wiring/cabling/conduits downward to the upper surface of the base portion 701. This will keep the wiring/cabling/conduits securely within the clip even in difficult weather and/or installation conditions. In a further preferred embodiment, some or all of the edges of the clip are rounded or beveled to prevent damage the sheathing of the wiring/cabling/conduits.

The clips 301 and 305 may be identical (size and/or shape), or different, depending on the projected installation. For example, the clips 305 may be larger than the clips 301, when they are used for bigger cabling, such as truck cable for AC micro-inverters. The clips may be sized differently, but have identical shapes, or have differing shapes but sized identically, again depending on installation. Preferably, at least one clip has a base portion 701 used to affix (permanently or removably) the clip to the lower surface of the PV module 100. As discussed above, the clip may be affixed by bonding, epoxy, tape, glue, screws, rivets, or any convenient method. The s-bend 702 is used to level wire/cable clip portion 708 to the module 100 upper surface 110, and keeps wires/cables off the roof surface. The flat base 701 is sufficiently attached to the PV module lower surface 105. The downwardly projecting tang 717 may be used for ease of installation of the clip onto the PV module. The base 701 may include a bias which acts to keep the clip pressed to the PV module edge.

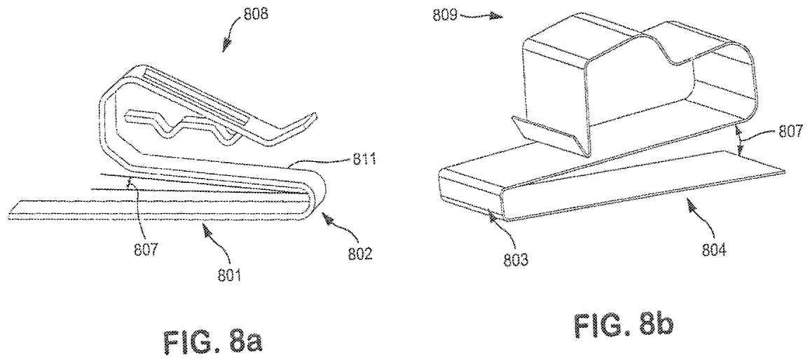

FIGS. 8a and 8b show other preferred embodiments that can be used in the present invention. The clips are modified Heyco SunRunner and SunRunner 2 clips, as discussed above. The flat portions 801 and 804 are bent approximately ˜180 degrees, to extend under the wire/cable clip portions, 808 and 809, respectively. More preferably, a bending radius of 1.2 mm to 3.0 mm, 802 and 803, is used to clear the wire/cable clip portion on the module 100 upper surface. Even more preferably, a bending angle of about 5 degrees to about 10 degrees, 807, is used for a flat portion 811 that raises the wire/cable clip portion on the top of the module 100 upper surface, and prevents wires/cables from touching the module upper surface.

The preferred method of installation of the module 100 on a composite shingle roof comprises applying a layer of Peel-And-Stick (PAS) tape to the bottom surface of the rigid lower layer 130. Positions of the PAS tapes are designed for common roof shingle course width, nominally about 5⅝ inches apart (FIG. 1b). Preferably, the tape layer 160 comprises a suitable double-stick tape, such as, for example but not limited to, a self-sealing tape having a formulation of resins, thermoplastics, curing rubbers, and non-curing rubbers. The double-stick tape has adhesive on both sides. When manufactured, the double-stick tape has a release layer on each side to prevent adhesion. One release layer is advantageously removed during the process of manufacturing the modules. The exposed adhesion side of the tape layer 160 is positioned on and adhered to the bottom surface of the rigid lower layer 130 before shipping the module 100. Then, during installation of the module 100, the remaining release layer is removed so that the module can be adhered to the surface of an existing roof. The surface of the existing roof is cleaned and suitably prepared to receive the module 100. After installation, suitable pressure is applied to the upper layer 110 of the module 100 to permanently adhere the module to the surface of the roof. In one preferred embodiment, The PAS tape 160 comprises plural Butyl tape in an array of, for example, 8 rows by 4 columns of tape-squares. Tape size can be, but not limited to: 2×4 inches to 4×4 inches. Preferably, the lower edge of the butyl tape is aligned approximately with the lower edge of each shingle course for installation, but the upper edge of the butyl tape may be spaced somewhat from the top edge of the module 100.

Once the PV module is installed on the roof, the wiring/cabling/conduits/trays are installed by simply pressing them into/onto the clips. The wiring/cabling/conduits/trays are then connected, pulled tight, and run to the appropriate junction box.

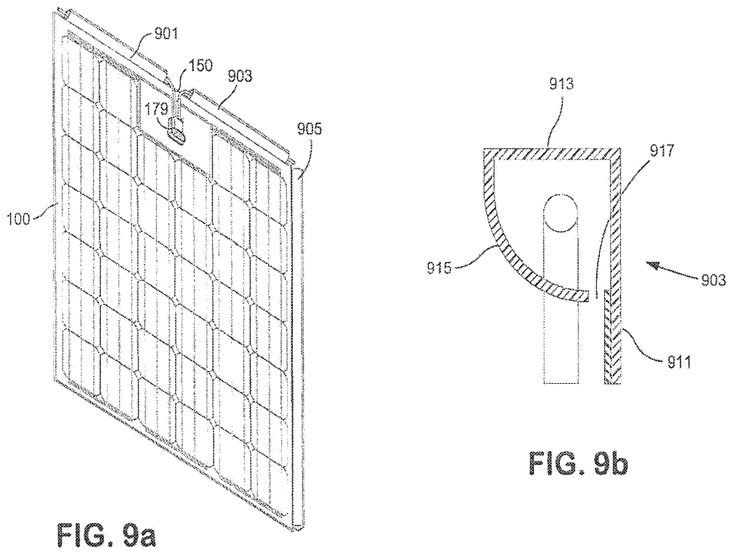

FIGS. 9a and 9b are perspective and partial cross-section views of an embodiment using cable trays instead of (or in addition to) the wiring clips. This embodiment provides improved weather protection for the wiring/cables/conduits, prevents workers from tripping over or otherwise disturbing the wires, and provides an enhanced aesthetic appearance. Of course, whole or partial wiring trays may be used in conjunction with clips 301 and/or 305, depending on the desired installation. Preferably, the cable trays 901, 903, and 905 comprise rigid and/or semi-rigid and/or bendable UV and/or weather resistant plastic sheaths having a smooth low profile and a flat bottom cross section, as best seen in FIG. 9b. In one preferred embodiment, cable trays 901 and 903 are affixed to the edge 150 of PV module 100, to accommodate at least the homerun cabling. The tray 905 may be affixed to another side edge of the PV module 100. Of course, cable trays may be provided on one, two, three, or all four edges of the PV module 100. In another preferred embodiment, cable trays can be installed peripheral to the PV module 100 with PAS Butyl tape. The trays are preferably parallel to edges of the PV modules. Each PV module edge may have one, two, three, or more cable trays coupled in series or in parallel. For parallel cable tray installations, each cable tray may be coupleable (releasably or permanently) to one or two adjacent cable trays. The cable trays may be solid, perforated, meshed, or any convenient structure.

In FIG. 9b, the tray 903 preferably comprises a quarter-circle shape having a first, straight side 911, a second straight side 913, and a curved side 915. Preferably, a gap 917 is provided between a distal end of the curved side 915 and a side portion of the first side 911. Note that a distal end of the first side 911 extends beyond the gap 917. This is to make it easy for a workman to lay one or more wires/cables/conduits onto the extended portion of first side 911, and sliding it down through the gap 917, where the above-described geometry keeps the wires/cables/conduits secured in place within the cable tray 903.

Preferably, the cable trays are affixed to the PV module 100 edges with liquid adhesives, tapes, clip, crimp, bolts, screws, rivets, etc. In the most preferred embodiment, the cable trays are affixed to the PV module edge(s) with one or more clips, legs, fixtures, etc. In another preferred embodiment, the cable trays are installed peripheral to the PV module 100 with PAS Butyl tape. The attachment may be permanent or releasable. Preferably, the tray can be affixed to the PV module without tools, either on the roof or adjacent thereto. Of course, the tray may be affixed to the PV modules in the factory. In a preferred embodiment, the clips 301, 303, and 305 may be constructed for use to support the wiring/cables/conduits or to couple to a corresponding receptacle (preferably a biased receptacle) in the cable tray.

Integrated wire management systems preferably protect electrical cables and connecters from UV, and harsh environmental conditions like snow, sleet, rain, animals, etc. In addition, integrated wire management enhances modules' aesthetics by covering junction boxes and the conductor wires to provide a uniform appearance of the modules and module arrays. Further features may include wire trays with covers, removable and/or hinged. Preferably, the wire tray structures described below are made of integral pieces of UV-resistant, water-proof, semi-rigid, or rigid plastic. Both integrated wire tray and cover are preferably made of plastic materials (not metal) to eliminate any grounding requirement. Trays may be made of hard plastic to provide rigidity. Covers can also be made by either elastic plastic or rigid plastic materials. Preferably, the covers are flexible enough to be removably coupled to the base. Various shapes and dimensions of integrated wire trays and covers can be employed for different applications, e.g., minimizing sun-shading on the modules, reducing accumulations of leaves and debris, enhanced wind load resistance, enhanced water and snow seals and shedding.

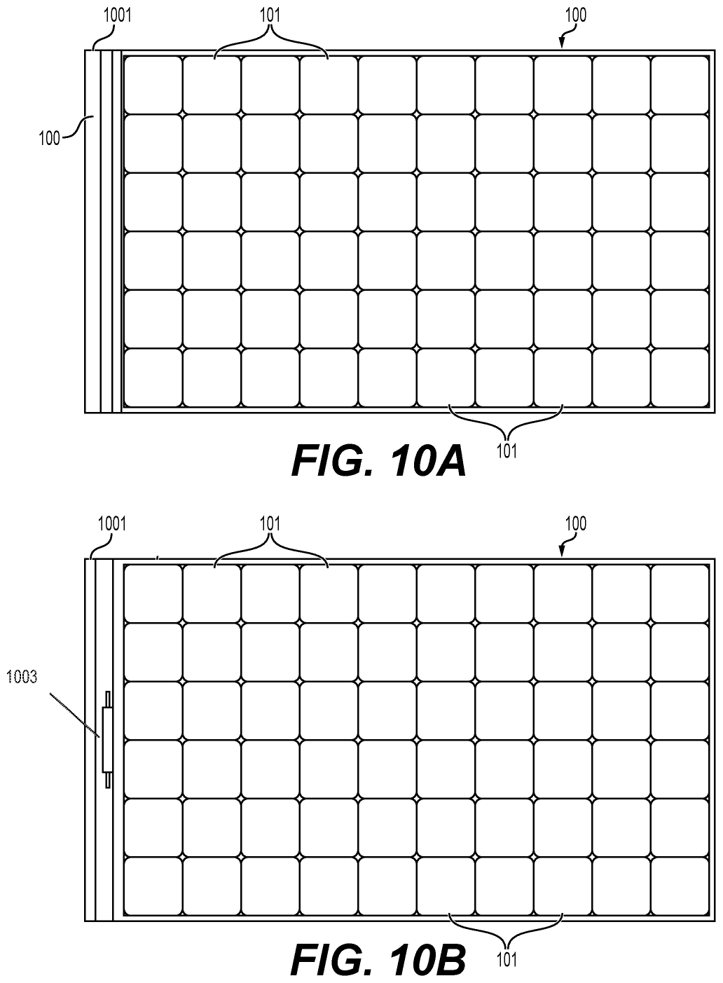

FIG. 10a is a front view of the solar module with integrated wire management, with a wire tray cover attached. The solar module 100 includes a ten by six, 2-dimensional matrix array of solar cells 101. At one end of the module, a top cover 1001 of a wire tray 1002 is shown. FIG. 10b is similar to FIG. 10a, but shows the module with the wire tray cover 1002 removed. A junction box 1003 is preferably centrally-located in the wire tray 1001, and preferably contains electrical connection circuitry and wiring for connecting together outputs from the solar cells 101. FIG. 10c is a view of the bottom of solar module 100, showing the bottom of the wire tray 1002. FIG. 10d is a side view of the solar module with on-board wire management, with a wire tray cover attached, with further structure to be described below.

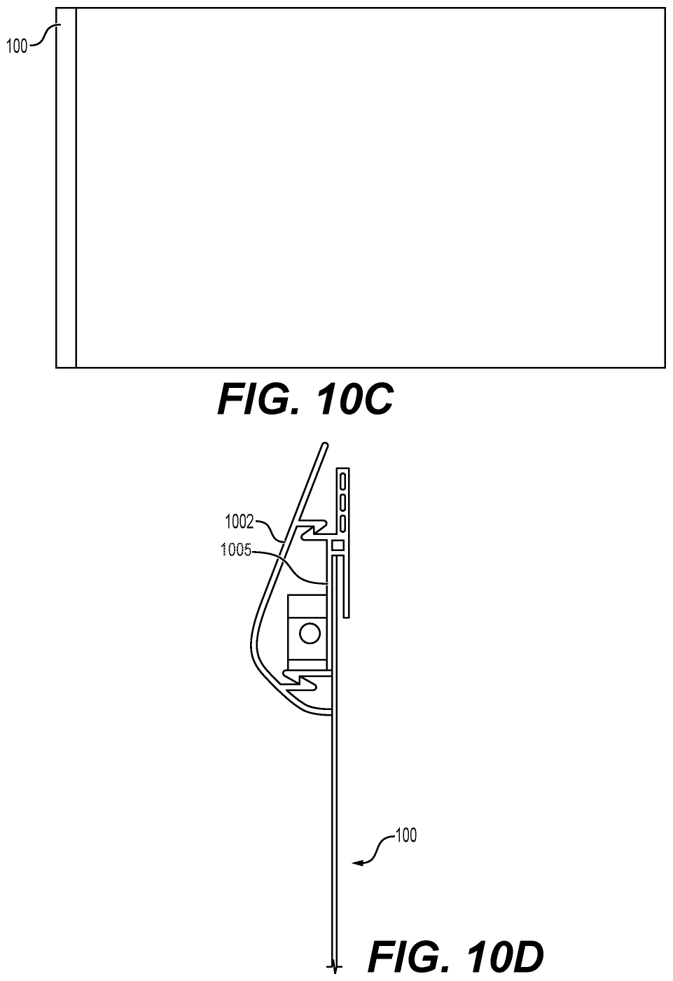

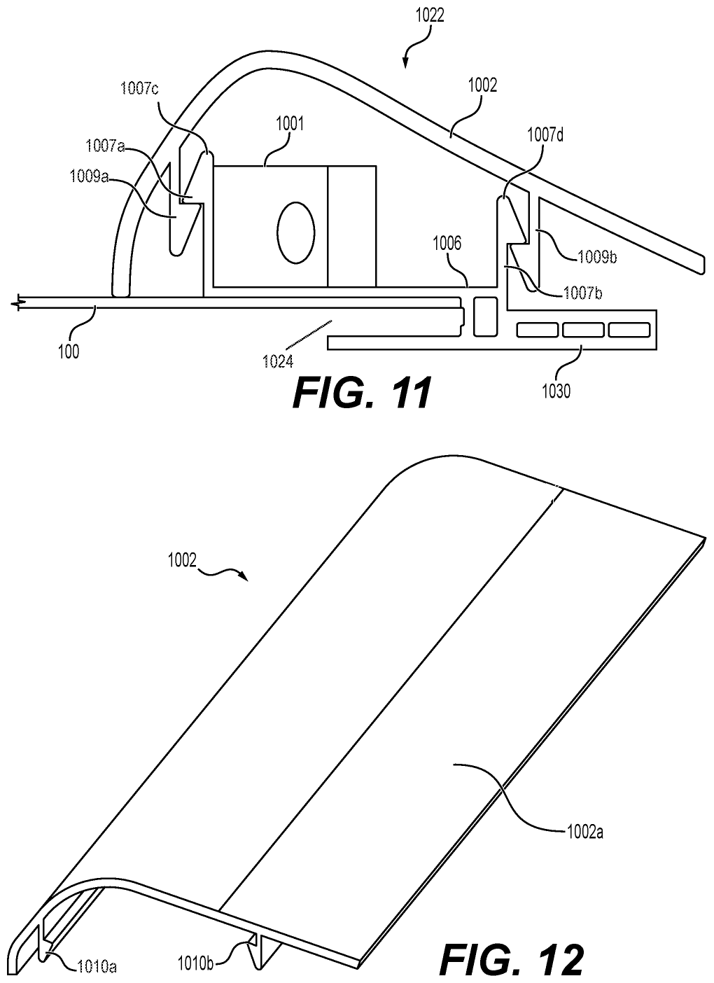

FIG. 11 is a close-up cross-sectional view of the FIG. 10b module, with cover attached. In this embodiment, the wire tray cover 1002 is preferably a single, integral piece of weather resistant polymer, such as but not limited to Polyvinyl Chloride, Acrylonitrile Butaduene Styrene, Polycarbonate, Polyphenylene Ether, Polyamide, etc. A wire tray base 1005 underlies the cover 1002, and is affixed to the module 100 via glue, epoxy, screws, thermal bonding, etc. Preferably, the base 1005 is also a single, integral piece of plastic, such as but not limited to Polyvinyl Chloride, Acrylonitrile Butaduene Styrene, Polycarbonate, Polyphenylene Ether, Polyamide, etc. The base 1005 preferably has a horizontal surface 1006 (generally parallel to a top surface of the module 100), and two perpendicular (vertical) portions 1007a and 1007b. Each of these vertical portions has an apex 1007c and 1007d, respectively. Preferably, each vertical portion has a clip portion 1008a and 1008b, respectively, generally comprising a horizontal surface, although acute angles may be provided for greater security and sealing. As shown, the wire tray cover 1002 has matching vertical portions 1009a and 1009b, with complementary apexes 1009c and 1009d, and complementary horizontal clip portions 1010a and 101b. Again, these clip portions may be generally horizontal and/or acute in angle. Note that the cover 1002 preferably comprises an non-symmetrical, curved shape designed with a wing 1002a that slopes downward more gradually that the inner slope 1002b. This shape is especially designed to channel water and debris away from the solar module 100 and toward the outer edges of the module and minimize shading of sun light. Such a design keeps the wires inside the tray and properly guided, enhancing speed of installation.

FIG. 11 also shows cable 1020, a junction box 1022, and adhesive attachment 1024. This attachment may comprise suitable glue, silicone, epoxy, thermal bonding, screws, clips, etc., and affixes the wiring tray onto the module 100. An integrated spacer 1030 may be provided at the edge of the wiring tray base 1006 to couple to adjacent solar modules 100. Note that the spacer 1030 may include one or more voids 1032 for flexibility and thermal management. The integrated wing/flange structures hold wires and cables down in wire tray, and speeds module interconnection during installation.

FIG. 12 is a perspective view of the FIG. 11 embodiment, showing the cover 1002, clip portions 1010a and 1010b, and wing portion 1002a.

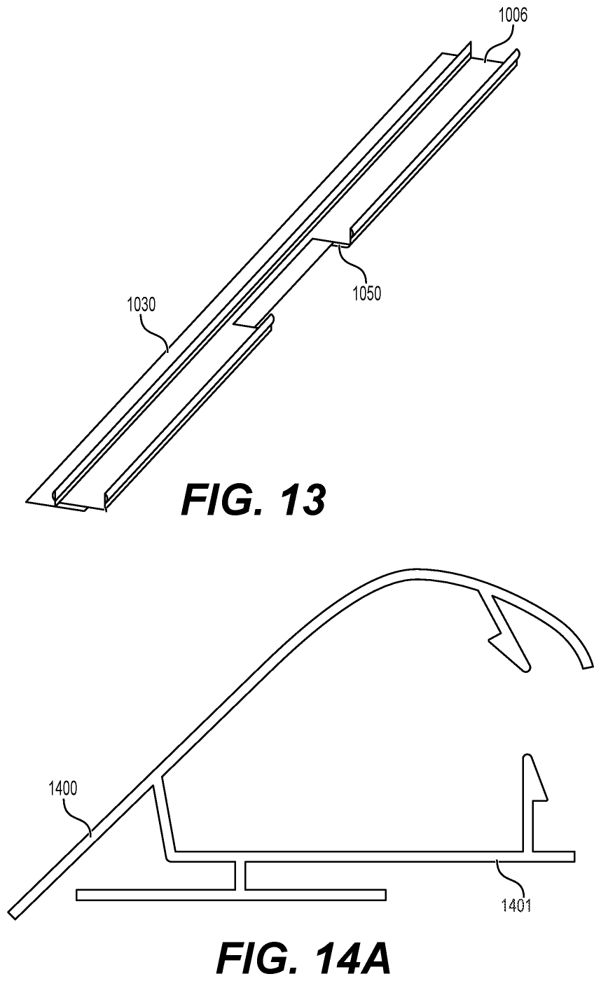

FIG. 13 is a perspective view of the FIG. 11 embodiment, showing the base 1006, the clip portions 1008a and 1008b, and the spacer portion 1030. A cut-out or notch portion 1050 may be provided in the central portion of the base 1006, to accommodate space for the junction box location, to be described below. As shown, preferably the notch portion 1050 is only provided in the tray 1006, and not the spacer 1030.

Preferably, both the integrated wire tray 1006 and cover 1002 are made of plastic materials to eliminate grounding requirement. Trays are preferably made of hard plastic to provide rigidity. The covers 1002 may be made by either elastic plastic or rigid plastic materials. Various shapes and dimensions of integrated wire trays and covers can be employed for different applications, e.g., minimizing shading on modules, reducing accumulation of leafs and debris, enhanced wind load resistance, enhanced water and snow seal.

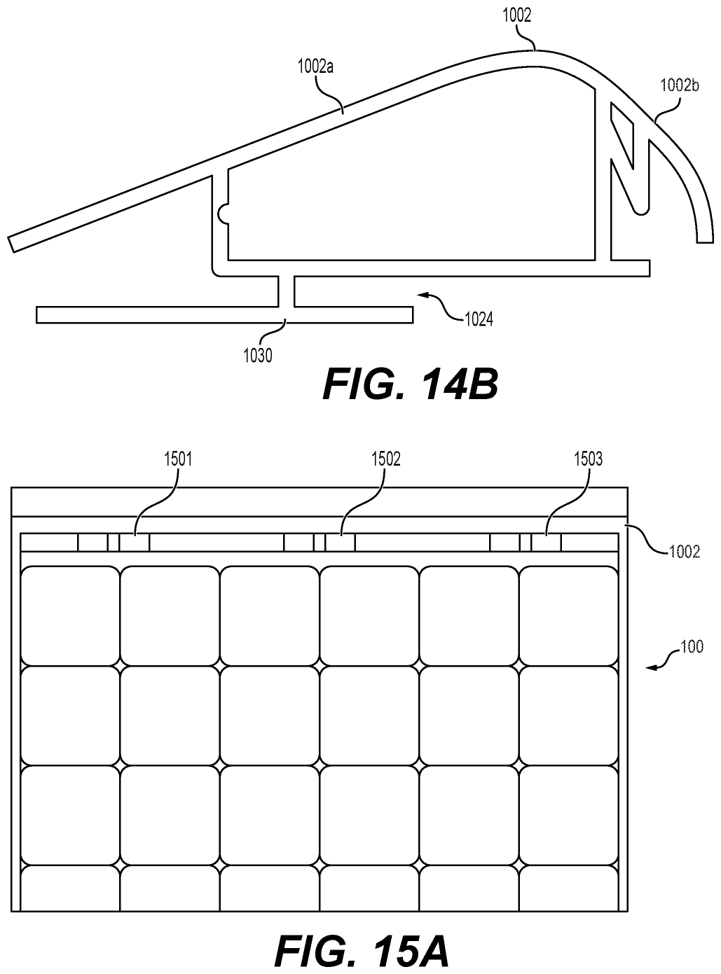

FIG. 14a is a cross-sectional view of an embodiment where the wiring tray cover and base are one, single, integral piece, with a hinge 1401 on at least one side. The preferred hinge is a notch in the vertical sidewall 1400. The notch may be semicircular in shape, triangular in shape, trapezoidal in shape, or any convenient shape. Of course, the hinge may comprise other structures such as a typical three-piece hinge with two side plates and a connecting pin.

FIG. 14b is a cross-sectional view of an embodiment where the wiring tray cover is hinged, showing the cover closed and locked. Note the substantially vertical wall 1402 in the spacer 1030. This vertical wall 1402 may be designed to provide flexibility to the horizontal portion of the space to allow flexibility what coupling the wiring tray to the solar module and allow cover section to open wide for wire and cable handling.

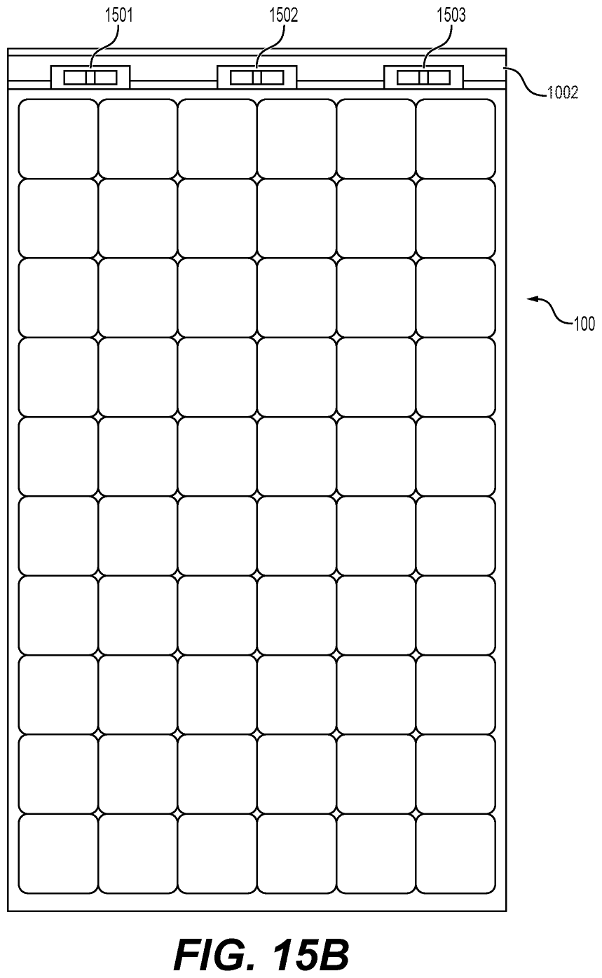

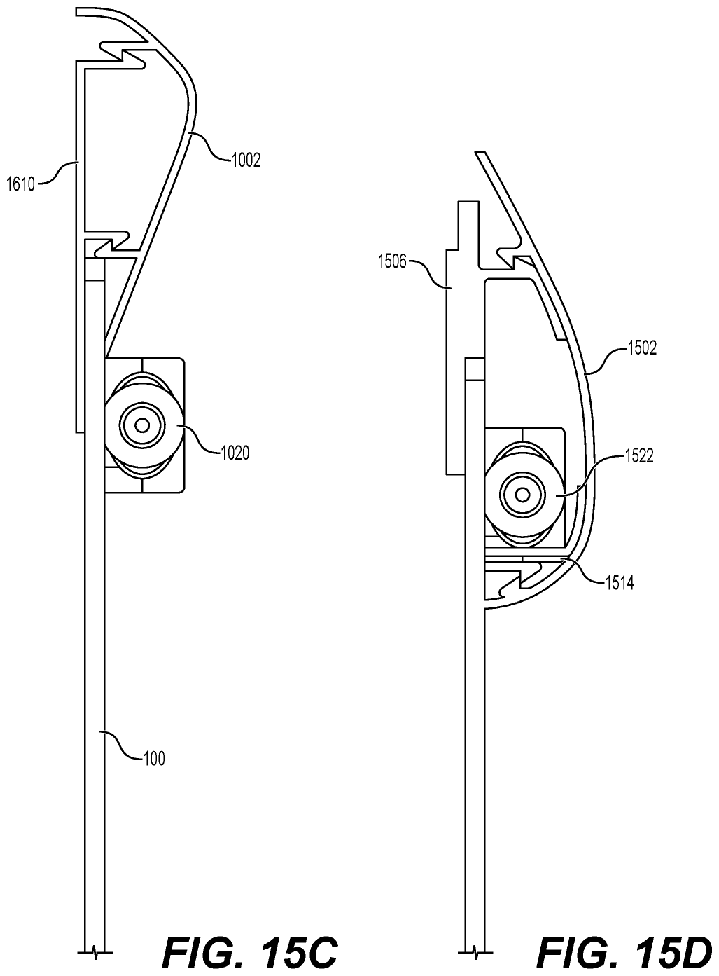

FIG. 15a is a top plan view of an embodiment showing the module 101, featuring the wire tray base 1006 and the cover 1002 at the shorter side of the module. Of course, one or more of the wiring tray assemblies may be provided on any side of the module, or plural sides of the module. In the FIG. 15 embodiment, decentralized junction box structures 1501, 1502, and 1503 are provided to handle the electrical connections from one sub string of solar cells, each. It should be noted that there will be a notch in the wiring tray base for each such junction box. FIG. 15b is a top plan view of another embodiment showing decentralized junction box structures 1501, 1502, 1503 are positioned under the cover 1002. FIGS. 15c and 15d are side views of the embodiments FIGS. 15a and 15b, respectively. In FIG. 15c shows an embodiment wherein the cover 1002 is more sloped, and the junction box 1020 is disposed outside of the cover 1002. In FIG. 15d, the junction box 1522 is disposed on the base 1506, under the cover 1502. The Vertical wall-wing structures 1514 and 1515 are used to couple the cover 1502 to the base 1506, as will be described in greater detail below.

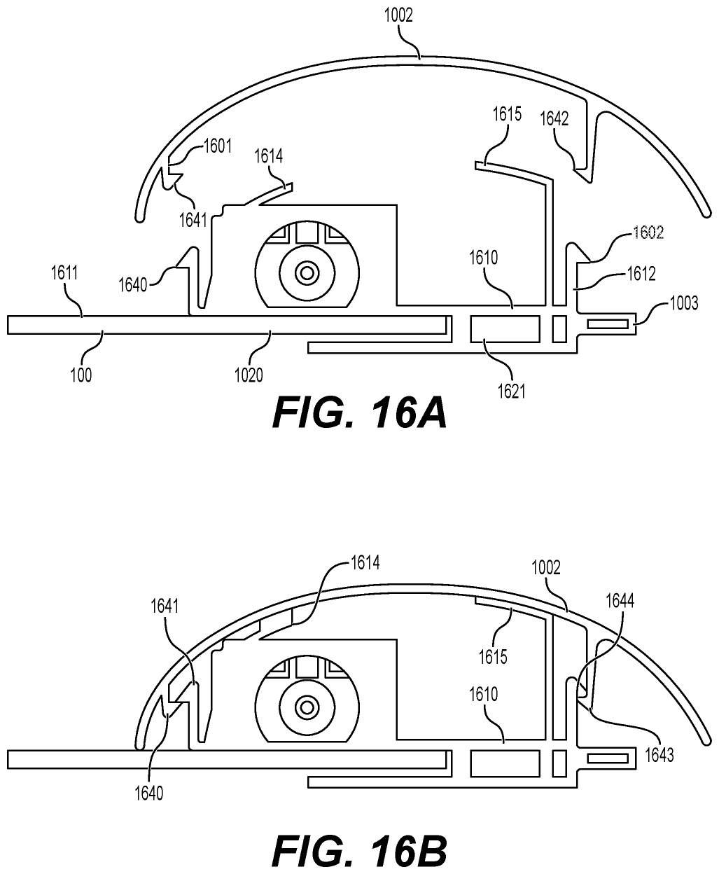

FIGS. 16a and 16b are side views of preferred embodiments showing the wire tray and cover. In FIG. 16a, the cover 1002 is more semicircular, dome shaped to deflect water and debris. The cover vertical walls 1601 is shorter that the vertical wall 1602. The base 1610 features vertical walls 1611 and 1612. Base wings 1614 and 1615 are angled at a preferably obtuse angle with respect to their corresponding walls, to provide a biasing spring-like mechanism to keep the cover 1002 firmly affixed to the base 1610. Wings 1614 and 1615 also function as cable/wire retainers to keep the cables, wires, and connectors down in the tray to ease the installation of the covers. Voids 1621, 1622, and 1623 are preferably provided to add flexibility to the wire tray mechanism during installation and use. The base wings 1614 and 1615 may each comprise a substantially vertical wall portion coupled at an obtuse angle with respect to a contact portion, which contacts an interior surface of the cover. Flanges 1641, 1642, 1643, and 1644 are provided to affix the cover to the base, as will be describe below.

In FIG. 16b, the cover 1002 is shown attached to the base 1610 via the flanges 1641, 1642, 1643, and 1644. Note that the base wings 1614 and 1615 are shown bent more to the horizontal than in FIG. 16a, to keep tension on the flanges, to keep the cover 1002 secured to the base 1610, keeping the flanges well engaged.

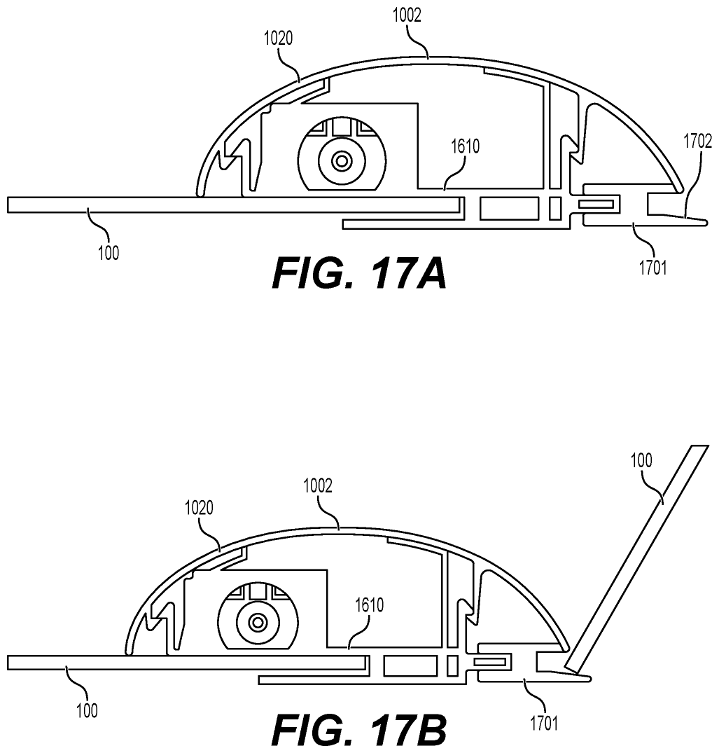

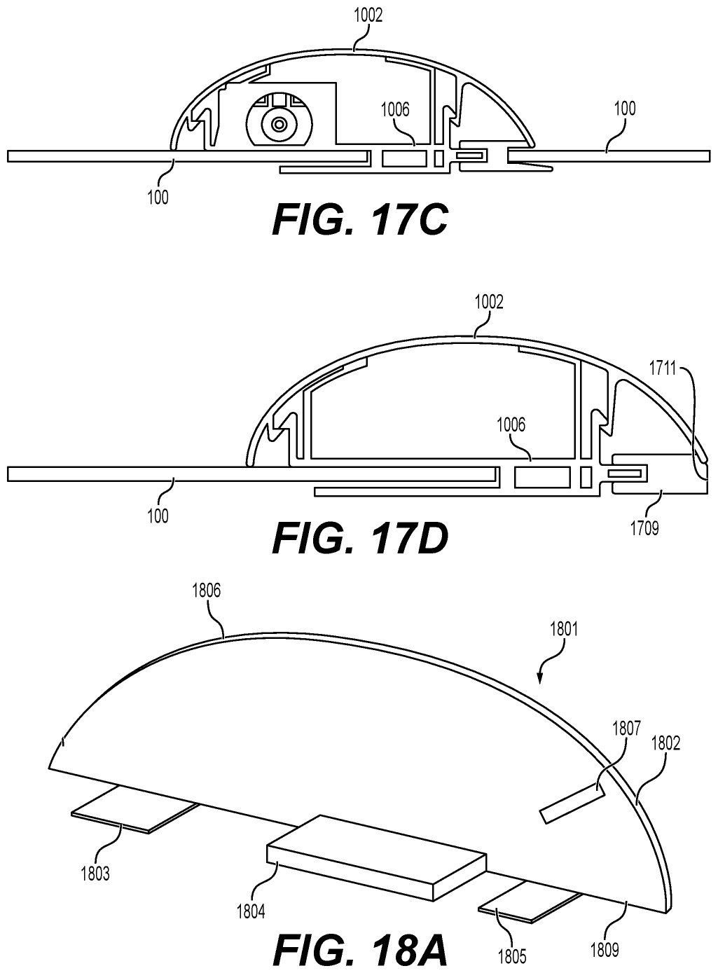

FIGS. 17a, 17b, 17c, and 17d, are side views showing the operation of preferred embodiments. In FIG. 17a, an inter-row spacer 1701 is provided for easy coupling of one 100 to and adjacent module 100. Preferably, the inter-row spacer 1701 is made of an elastic, polymer, or rubber material, to provide some flexibility, ease installation, and accommodate module dimension change with module temperature. As can be seen, an adjacent, next-row module 100 is leveraged into the spacer 1701, using the ramp-like surface 1702 of the spacer. FIG. 17c shows the completed installation of the next-row module 100. Note that the cover 1002 preferably contacts each of the adjacent modules 100. FIG. 17d shows an end-row spacer 1709, which has a vertical surface to cap-off the end of the module row. Note that indentation 1711 in the spacer 1709 is fitted to make a good seal with the bottom of the cover 1002. The inter-row spacers provide/enable fixed spacing between module rows and hold modules on same levelled plane. Thus, the module array will appear uniform from any perspective. The top-row (or last course) of modules has a spacer that is preferably mated to the cover to provide a sealing function to the wire tray and cover that prevents debris, water, snow, insects, etc. getting under tray cover.

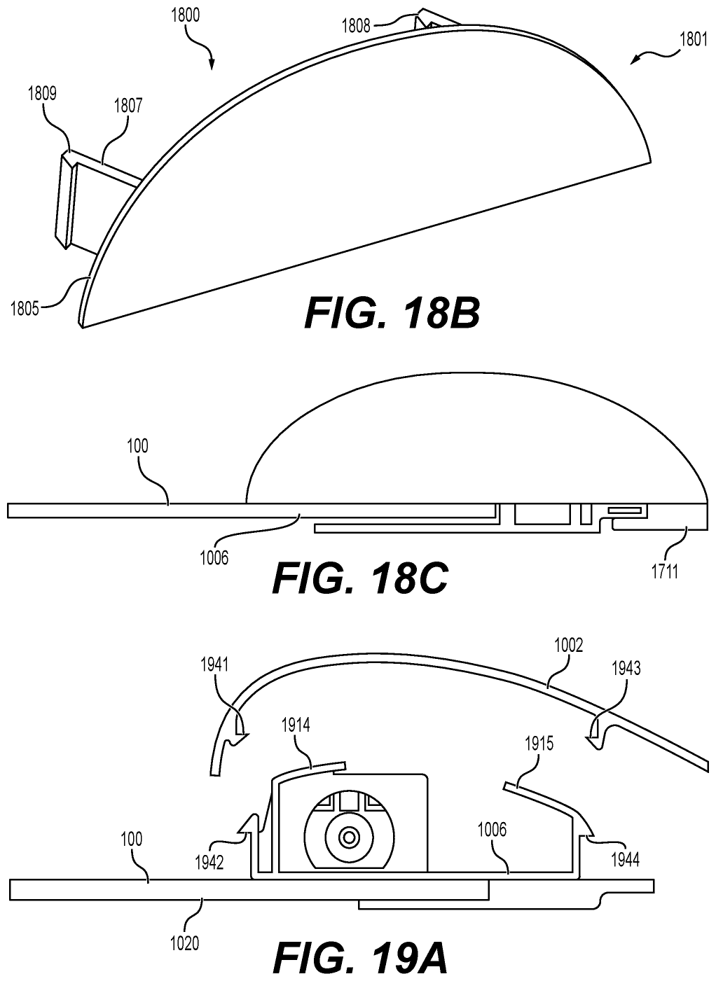

FIGS. 18a, 18b, and 18c are perspective views showing end cap structure, according to preferred embodiments. These end cap structures are designed to provide a weather-proof seal at the open ends of the combined wiring tray base and cover. In FIG. 18a, the end cap 1801 preferably comprises a semicircular piece of semi-rigid plastic 1802, matching the profile of the wire tray cover 1002. At the flat bottom edge of the end cap 1801 are preferably three tensile clips 1803, 1804, and 1805, projecting orthogonally from the flat piece 1802. These tensile clips preferably match with corresponding voids at the end of the base 1006, to align the end cap to the base. Substantially vertical walls 1806 and 1807 project orthogonally from the piece 1802, and have corresponding flanges 1808 and 1809. These flanges preferably couple with corresponding flanges at the end of base 1006, to secure the end cap in place. FIG. 18b shows the back side of the end cap, and FIG. 18c shows the end cap 1801 mounted to the wiring tray base 1006.

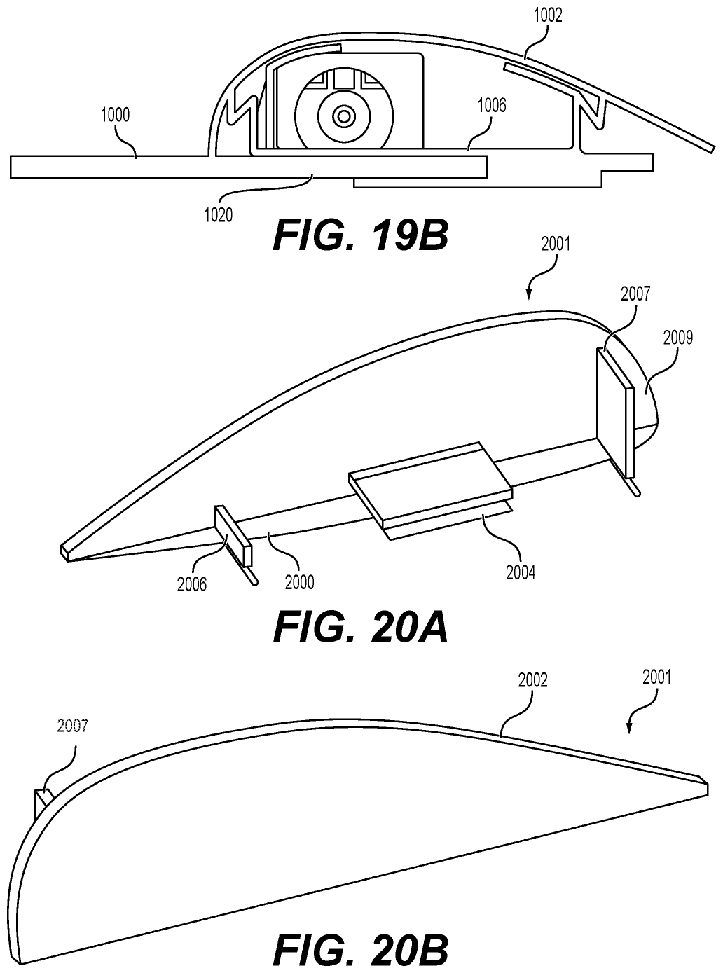

FIGS. 19a and 19b show an alternative embodiment where the cover 1002 slopes more gradually to the outside of the module 100. This asymmetrical wire tray cover design features a lower profile to minimize possible shading on the modules. The lower profile also reduces debris accumulation on the next up-slope modules. Similar to the embodiment of FIGS. 16a and 16b, biasing wings 1914 and 1915 are provided to keep tension on the connections between flanges 1941, 1942, 1943, and 1944, to keep the cover 1002 secured to the base 1006, and to hold the cables, wires, and connectors down in the tray base for ease of cover installation and removal. Note that the biasing wing 1914 is a separate structure from the vertical wall supporting the flange 1942, whereas, the biasing wing 1915 is supported on the same substantially vertical wall as the flange 1944. Of course, any combination of vertical walls, flanges, and biasing members may be adapted for any type of installation.

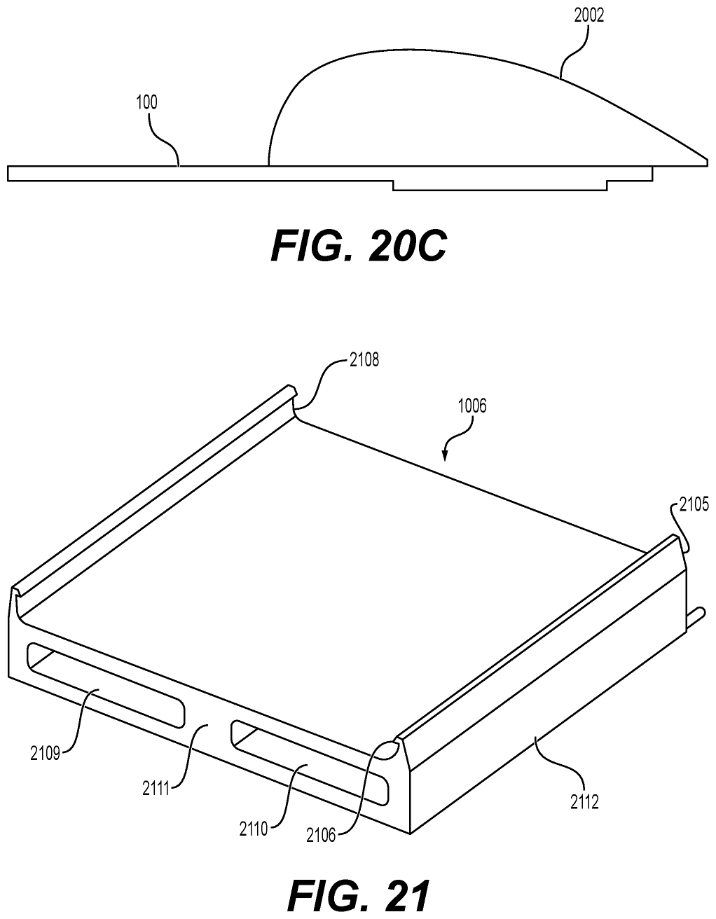

FIGS. 20a, 20b, and 20c are similar to the FIGS. 18a, 18b, and 18c, but featuring the more gradually-sloped profile to match the profile of the cover of FIG. 19a. In FIG. 20a, the end cap 2001 preferably comprises a sloped piece of semi-rigid plastic 2002, matching the profile of the sloped wiring tray cover 1002. At the flat bottom edge of the end cap 2001 a tensile clip 2004, projecting orthogonally from the flat piece 2002. This tensile clip preferably matches with a corresponding void at the end of the base 1006, to align the end cap to the base. Substantially vertical walls 2006 and 2007 (with 2006 being shorter than 2007) project orthogonally from the piece 2002, and have corresponding flanges 2008 and 2009. These flanges preferably couple with corresponding flanges at the end of base 1006, to secure the end cap in place. FIG. 20b shows the back side of the end cap, and FIG. 20c shows the end cap 2001 mounted to the wire tray base 1006. Thus, the end cap provides a uniform shape for the integrated wire tray/cover system. The end-cap protects the wire tray system from leafs, debris, insects, and snow, etc.

FIG. 21 is a perspective view of the base 1006, showing the vertical walls 2105 and 2107, together with their respective flanges 2106 and 2108. The base 1006 is preferably made of a single, integral piece of semi-rigid plastic. Voids 2109 and 2110 may be provided to enhance the light weight of the assembly, together with substantially vertical wall 2111 which provides flexibility during installation. Preferably, the base may be attached to the module 100 with one or more adhesives such as glue, epoxy, thermal resins, etc. Also preferably, the bottom surface 2112 of the base may have an adhesive, such as double-sided tape, to adhere the base to one or more roof shingles. Thus, the whole base's bottom surface 2112 can be adhered to shingle roof to provide sufficient wind resistance to the home run wire tray system. The base may be substantially 84 mm by 74 mm to ensure that the base will fit on a single tab of a shingle. The base's height of substantially 13 mm ensures wire tray system complies with the National Electrical Code (NEC) code.

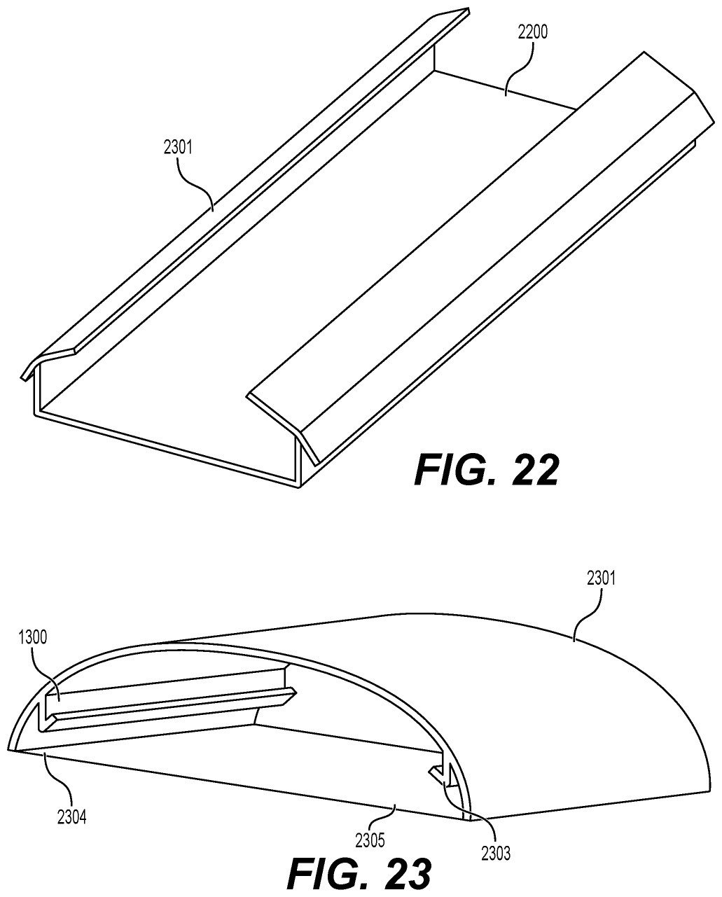

FIG. 22 shows an embodiment wherein a tray 2200 may be provided as the base piece, or as an insert into the base 1006. The tray 2200 also protects home run cables from touching the roof surface, for safety and to comply with NEC codes. The one-piece construction features integrated wings 2201 and 2202 to ease wire/cable installation, and/or to keep the cover tensioned against the base, as discussed above.

FIG. 23 is a perspective view of cover 2301 with substantially vertical walls 2302 and 2303, together with their respective flanges 2304 and 2305. Preferably, the top of the cover is smooth, rounded, and symmetrical to minimize wind-resistance, prevent debris accumulation, and reduce the number of accessories required as described below.

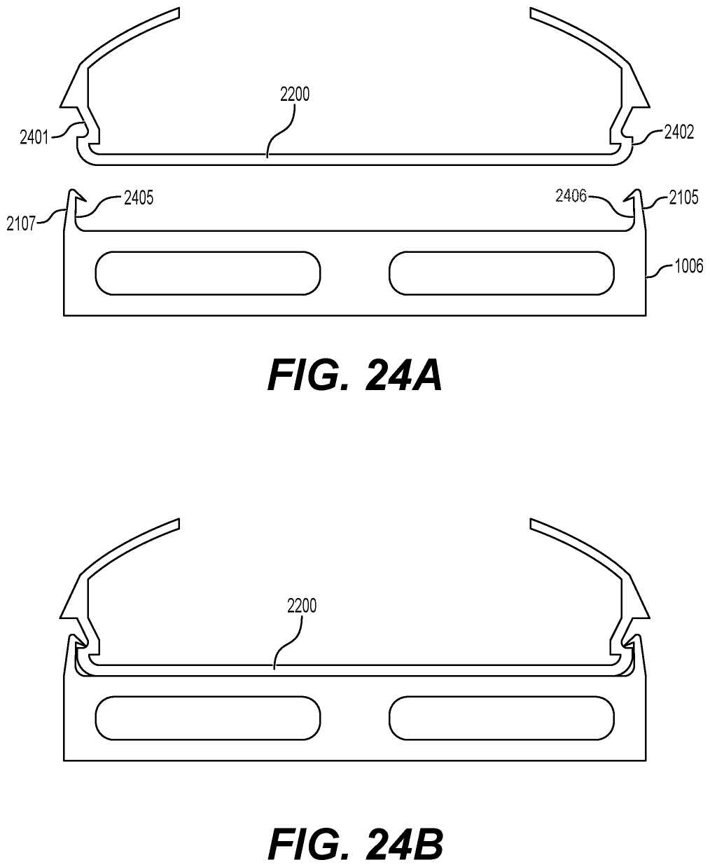

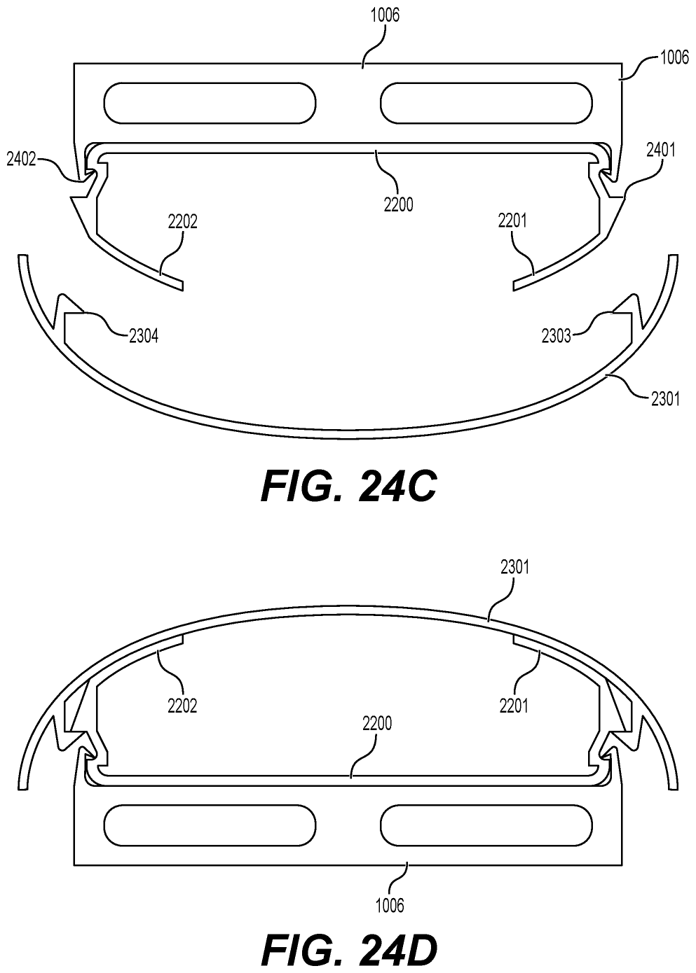

FIGS. 24a, 24b, 24c, and 24d show the home run tray assembling process for the FIGS. 21-23 embodiment. In FIG. 24a, the tray 2200 is inserted into the base 1006, with the tray flanges 2401 and 2402 engaging with respective base flange 2405 and 2406; as depicted in FIG. 24b. Next, as shown in FIG. 24c, the cover 2301 is inserted into the tray 2200, with the tray flanges 2401 and 2402 engaging with respective cover flanges 2303 and 2304. FIG. 24d shows the assembled base, tray, and cover. Preferably, the home run tray assembly can be disassembled and reassembled as needed for rework of photovoltaic systems.

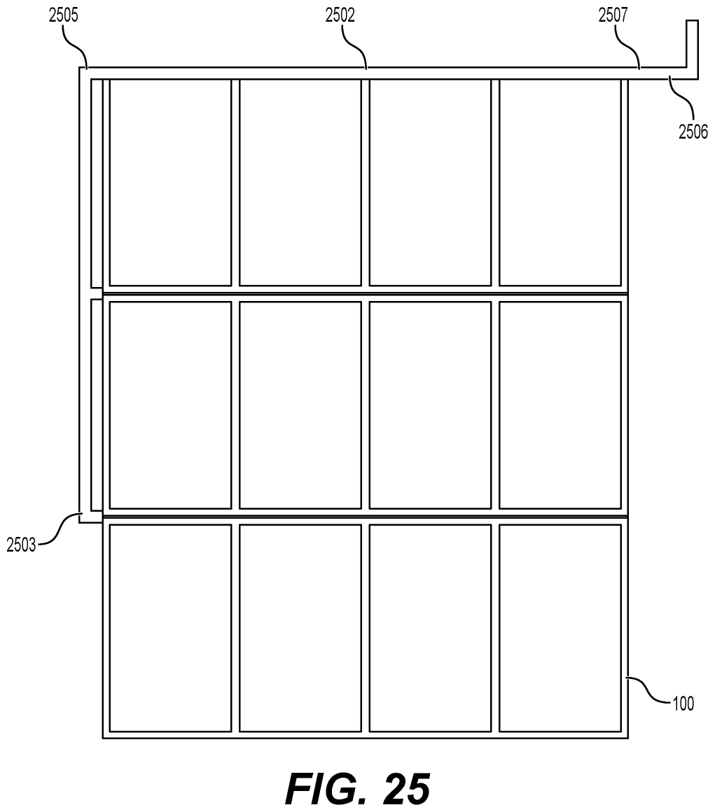

FIG. 25 shows the home run accessories which may be provided to enhance the appearance of the module, and to further add to the wind, water, debris-repelling qualities of the module. In FIG. 25, the module 100 has a home run wire tray 2501 along at least one portion (less than all) of one side of the module, and a home run wire tray 2502 along the entire portion of another (perpendicular) side of the module. L-joint 2503 and T-joint 2504 are provided to accommodate the wiring from the solar cells into the wiring tray 2501, and to run the wires along the tray 2540. L-joint 2505 is provided to run the wiring from tray 2501 to tray 2502 (and to route any wires coming from the solar cells adjacent thereto). An L-joint is provided at an end of the tray 2502, to route the wires to a junction box and/or inverter (not shown). A transition joint 2507 is provided to route wires to a/the junction box. Each joint may comprise a base portion shaped generally similar to the shown covers, and having a cross-section generally similar to those shown in FIGS. 24a, 24b, 24c, and 24d, but necessarily having L-shaped, T-shaped, or transition-shaped outlines.

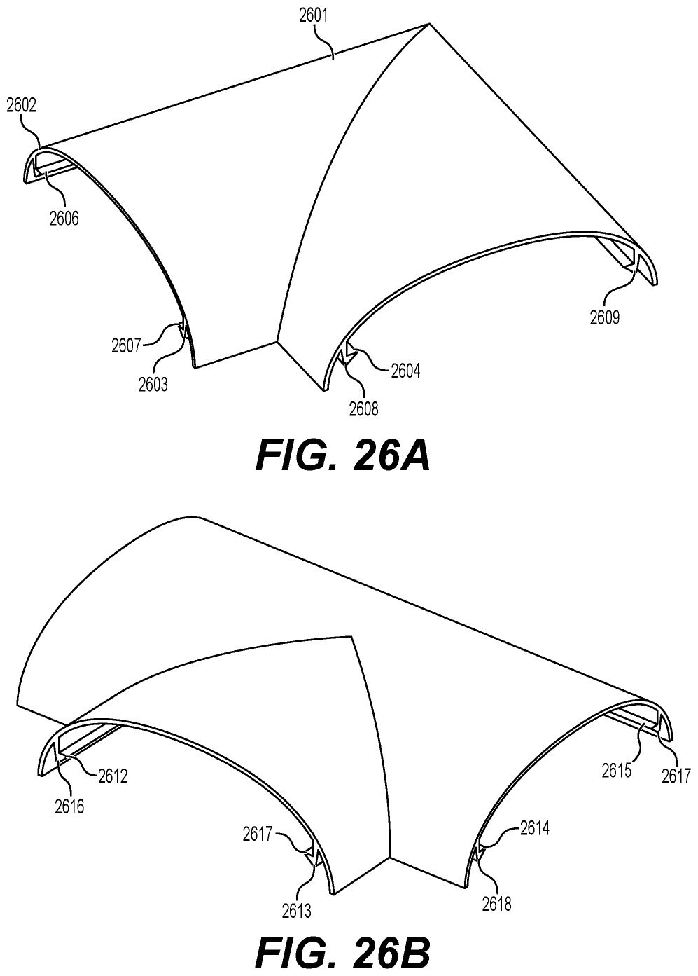

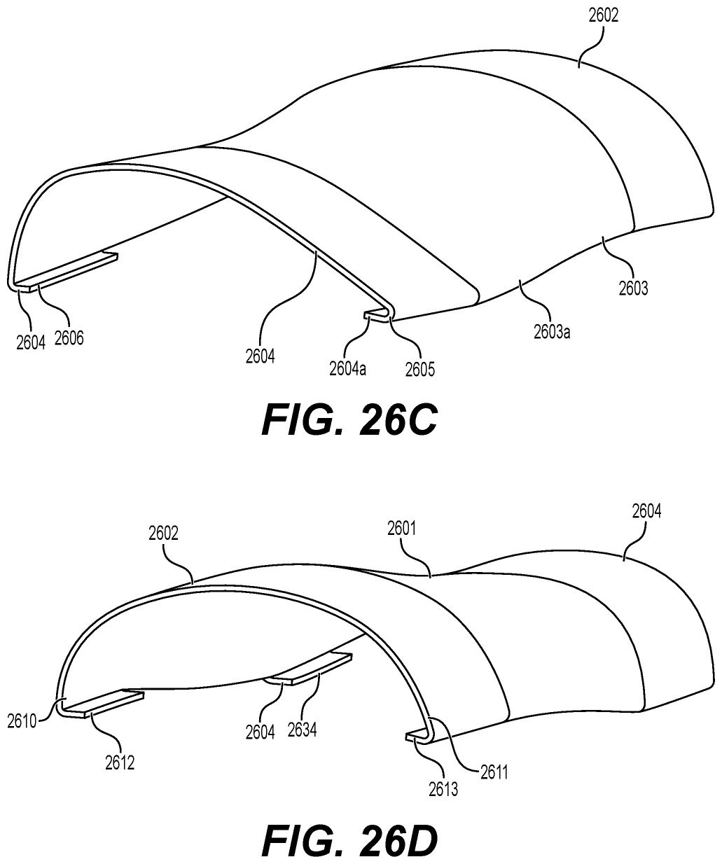

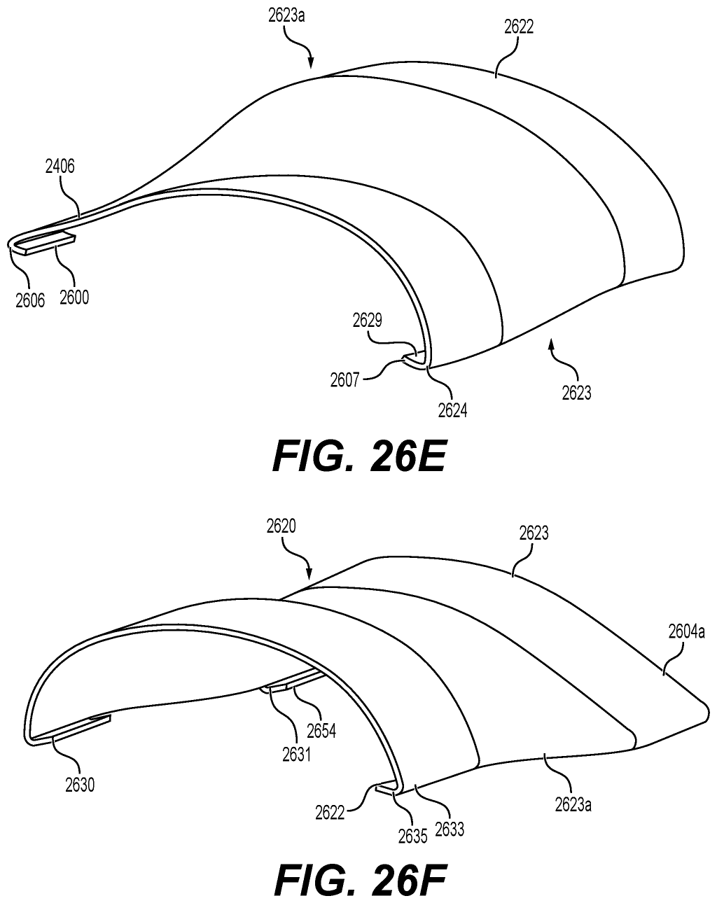

FIGS. 26a, 26b, 26c, 26d, 26e, and 26f are perspective views of the covers of the various joints discussed above. In FIG. 26a, an L-joint cover 2601 is shown, having substantially vertical walls 2602, 2603, 2604, and 2605, together with their respective flanges 2606, 2607, 2608, and 2609. In FIG. 26b, a T-joint cover 2611 is shown, having substantially vertical walls 2612, 2613, 2614, and 2615, together with their respective flanges 2616, 2617, 2618, and 2619. The covers are preferably smooth single pieces of integral plastic to prevent ingress of wind, water, and debris. Because of the symmetrical homerun tray cover design, only one L-joint cover and one T-joint cover design are used. Thus, part counts for installation is minimized.

FIG. 26c shows a perspective view of a left-transition cover which may be used to transition a lower-profile wiring tray into a higher-profile wire tray (such as from an on-board tray carrying relatively fewer wires to a tray having more wires). In FIG. 26c, the cover 2601 comprises a higher cover portion 2602, a transition (high-to-low) cover portion 2603, and a lower cover portion 2604. It can be seen that the transition portion 2602 and the lower portion 2604 each have a flaring, more gradually sloped cover portion 2603a and 2604a, to accommodate a base portion with a wider dimension in the width dimension than that of the base affixed to the higher portion 2602. Each high and low portion may include substantially vertical walls 2604 and 2605, together with corresponding flanges 2606 and 2607. The shape of the outline of 2602 and 2604 preferably matches the on-board tray cover and homerun tray cover for ascetically coupling between adjacent covers. FIG. 26d shows the left-transition cover 2601 from the opposite perspective. The vertical wall 2604 of the lower cover portion 2604 can be readily seen, together with its corresponding flange 2606. The high cover portion 2602 can be seen to comprise substantially vertical walls 1610 and 2611 together with their corresponding flanges 2612 and 2613. Again, these flanges will engage with corresponding flanges on the respective base portions.

FIGS. 26e and 26f are very similar to FIGS. 26c and 26d, but showing a right-transition cover 2620. Higher cover portion 2622 is adjacent transition cover portion 2623 which merges with lower cover portion 2624. Gradual sloping portions 2623a and 2624a provide a gradual slope in the width dimension. The shape of the outline of 2622 and 2624 preferably matches the on-board tray cover and homerun tray cover for ascetically coupling between the covers. Substantially vertical walls 2626 and 2627 are provided, with their respective flanges 2628 and 2629. Substantially vertical walls 2630, 2631, and 2632 are provided, together with their corresponding flanges 2633, 2634, and 2635.

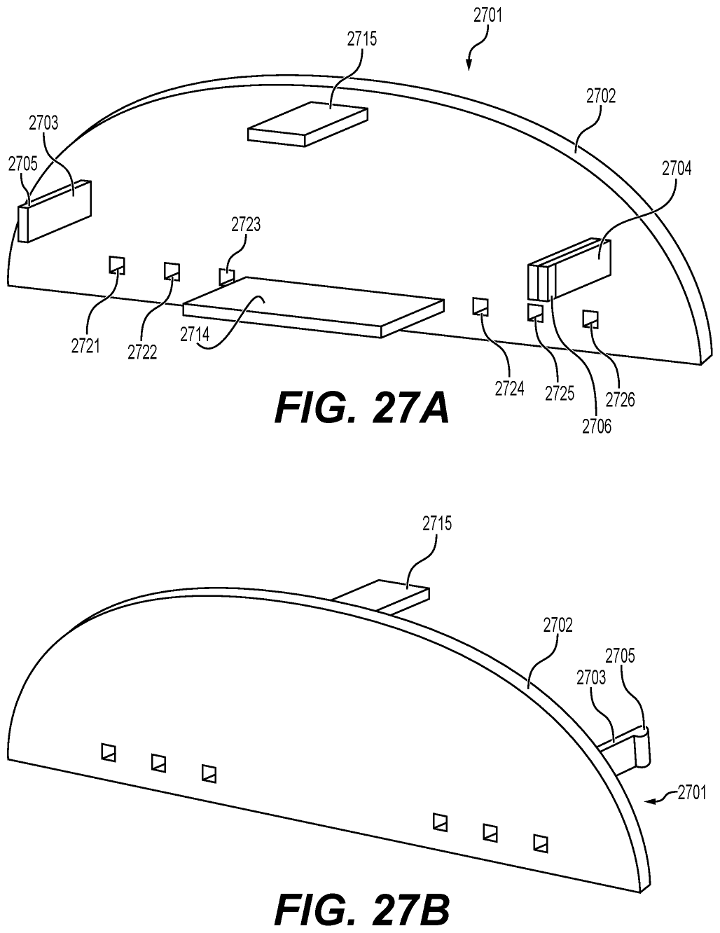

FIGS. 27a and 27b show an embodiment for home run tray-end caps 2701. As with the FIGS. 18a, 18b, and 18c embodiment, substantially vertical walls 2703 and 2704 are provided together with their corresponding flanges 2705 and 2706. The flat piece 2702 preferably has an orthogonally-projecting bottom tab 2714, and an orthogonally-projecting top tab 2715. These tabs are configured to engage corresponding void in respective tray and cover portions. The end cap 2701 features holes 2721, 2722, 2723, 2724, 2725, and 2726 at the bottom portion of the flat piece 2702. These holes may be provided for moisture drainage, as well as cooling of the air within the wire trays.

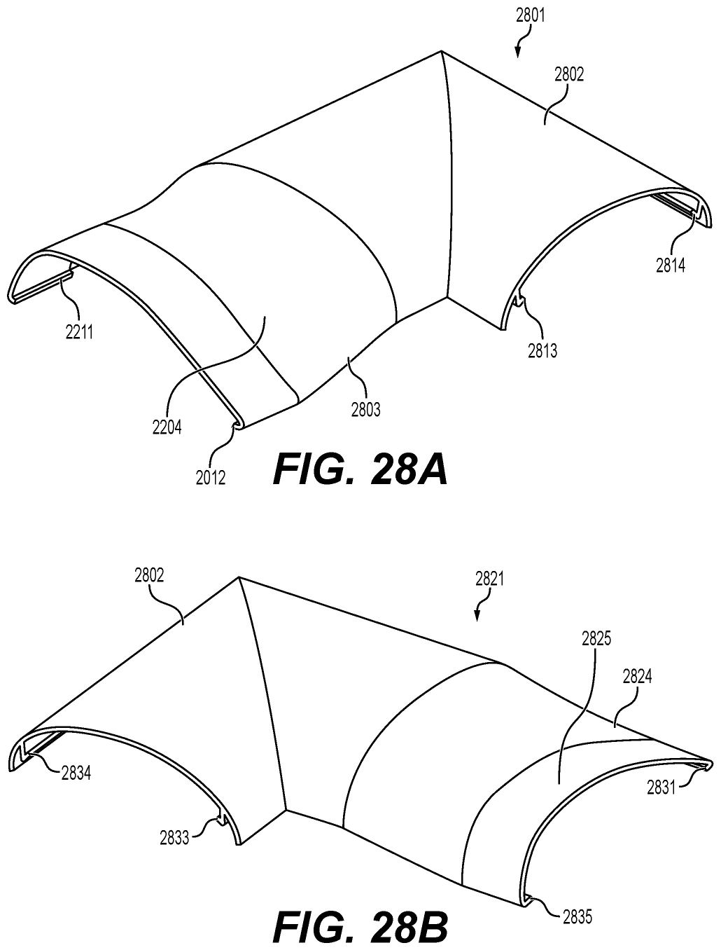

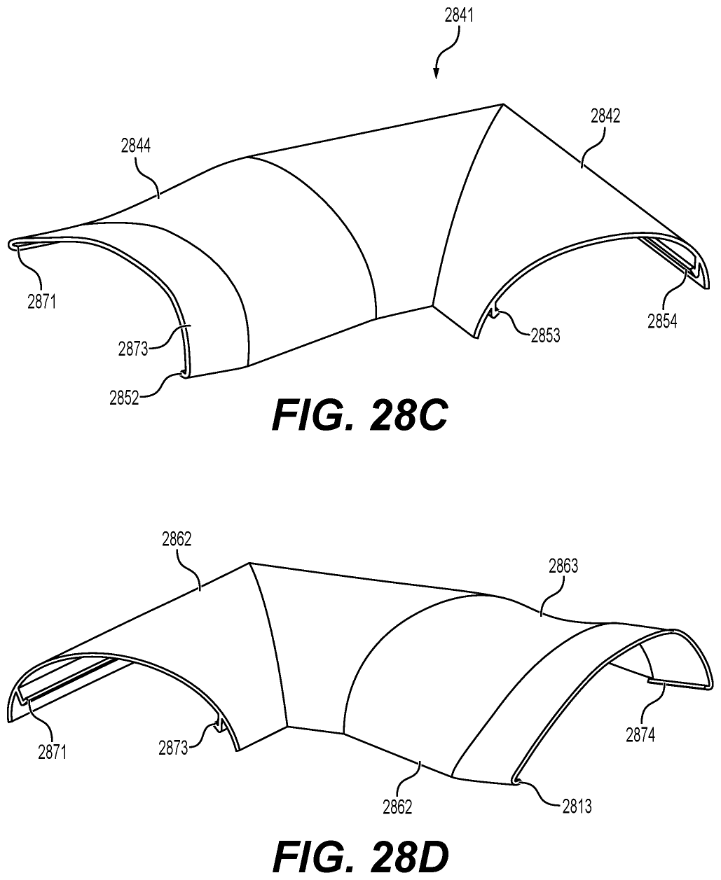

FIGS. 28a, 28b, 28c, and 28d are perspective views of cover portions combining L-joints with transition portions. In FIG. 28a, an L-joint with a left transition 2801 is shown. This comprises the L-joint 2802, the left transition 2803, including the flared portion 2804. As with the above-described embodiments, flanges 2811, 2812, 2813, and 2814 are configured to couple the joint 2801 to the underlying base(s). Preferably, these combined joints and transitions are made of a single piece of semi-rigid of semi-flexible plastic and/or rubber materials. In FIG. 28b, an L-joint with a right transition 2821 is shown. This comprises the L-joint 2822, the right transition 2823, including the flared portion 2824. As with the above-described embodiments, flanges 2831, 2832, 2833, and 2834 are configured to couple the joint 2821 to the underlying base(s).

In FIG. 28c, an L-joint with a left transition 2841 is shown, but with the flare going the opposite direction of the flare in FIG. 28a. This comprises the L-joint 2842, the left transition 2843, including the flared portion 2844. As with the above-described embodiments, flanges 2851, 2852, 2853, and 2854 are configured to couple the joint 2841 to the underlying base(s). In FIG. 28d, an L-joint with a right transition 2861 is shown, but with the flare going the opposite direction of the flare in FIG. 28b. This comprises the L-joint 2862, the left transition 2863, including the flared portion 2864. As with the above-described embodiments, flanges 2871, 2872, 2873, and 2874 are configured to couple the joint 2861 to the underlying base(s).

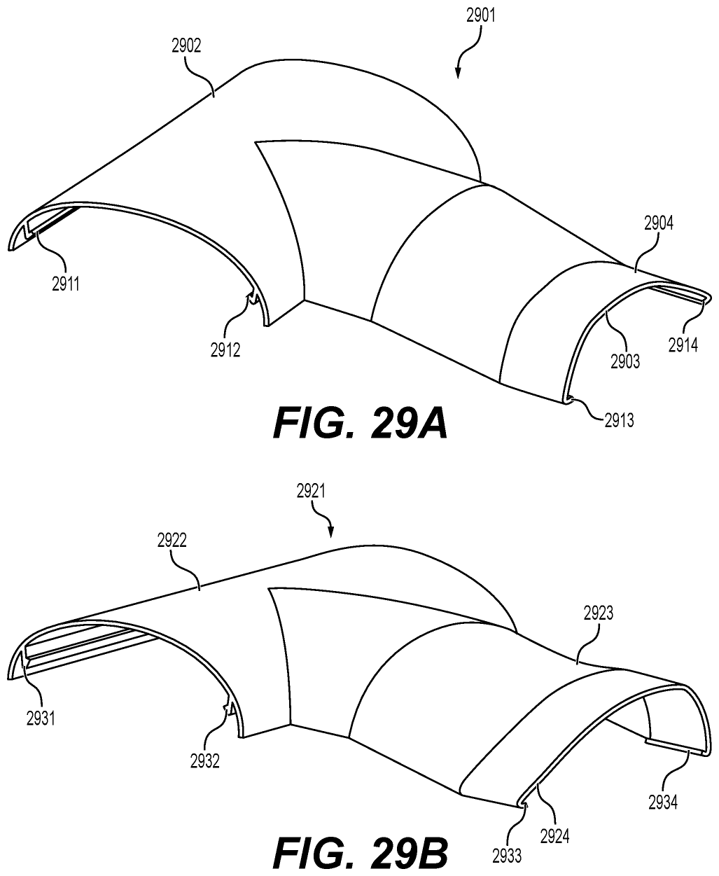

FIGS. 29a and 29b are perspective views of cover portions combining T-joints with transition portions. In FIG. 29a, a T-joint with a right transition 2901 is shown. This comprises the T-joint 2902, the right transition 2903, including the flared portion 2904. As with the above-described embodiments, flanges 2911, 2912, 2913, and 2914 are configured to couple the joint 2901 to the underlying base(s). In FIG. 29b, a T-joint with a left transition 2921 is shown. This comprises the T-joint 2922, the left transition 2923, including the flared portion 2924. As with the above-described embodiments, flanges 2931, 2932, 2933, and 2934 are configured to couple the joint 2921 to the underlying base(s).

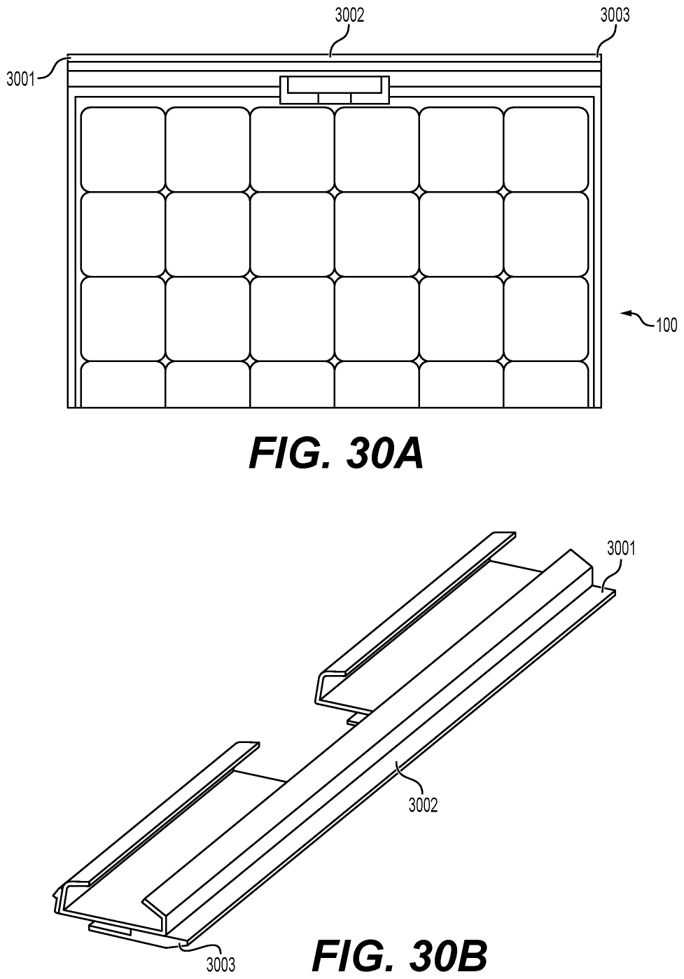

FIG. 30a is a section view of a solar module embodiment with integrated wire tray showing 3 mounting holes for easy module handling. FIG. 30b is a perspective view of the base 3006 of FIG. 30a, showing the mounting hole 3001 in greater detail. Integrated wire tray mounting holes 3001, 3002, and 3002 may be provided for easy module handling. By allowing the installer to use a carabiner, hook, or ring to secure the module for hoisting to the roof, it avoids the necessity to use a strapping system or laddervator method to hoist modules to the roof in a safe and code compliant method. The hole can be sized for suitable hardware mounting, such as carabiner clips, hooks, spring snap links, etc. for raising modules onto roofs. The holes may even be sized to accommodate a human finger and/or fingers and/or hand. Also, one or more indentations may be provided for allowing easy human-handling of the module(s). Additionally, the mounting holes 3001, 3002, and 3003 may also be used to secure the module/wire tray on roofs with adhesively attached polymer mounting hardware for enhanced wind resistance. This may offer a method of securing the modules on a pitched roof surface using fall-protection hardware as a temporary storage until the installer is ready to adhesively mount the module in the designated location.

Non-curing adhesives are preferably used for module installation. Two types of elastic adhesives are preferably used for module attachment on roof surfaces. One is curable with time and heat. The other is not cured. The modules preferably use non-curable thermoplastic adhesives for module attachment. The advantage of using non-cured adhesives for module attachment on roofs is that the module can be removed and replaced or re-installed as needed without altering or damaging the roofing surface and/or structure. Removal of modules can be done simply by using thermal means, such as but not limited to use a heating blanket.

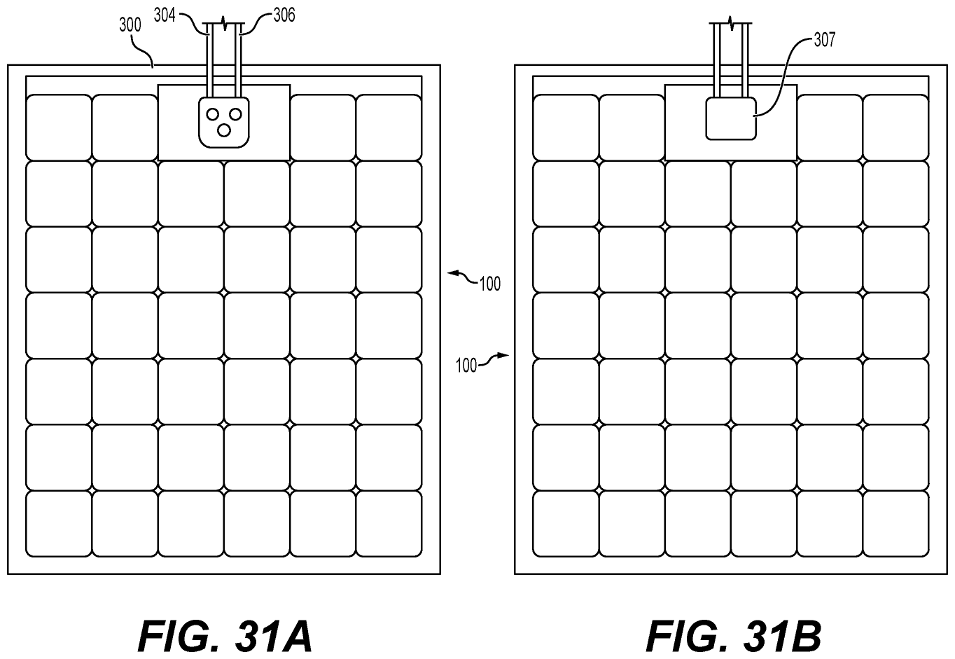

A UV blockage label is shown in FIGS. 31a and 31b. Preferably, the modules 100 use one or more top, surface-mounted junction boxes 3112, each preferably having waterproof conductors 3114 and 3116 for connection to the home run wiring, for example. To protect the junction box from UV light and heat from the sun, a module label 3118, preferably made with Aluminum film, is placed on the top and/or sides of the junction box. The Aluminum film is preferably anodized for an enhanced emission coefficient and reflection. The enhanced emission coefficient will dissipate heat from junction box effectively, and the enhance reflection of heat from ambient. In addition, Aluminum film blocks UV rays. The Aluminum film is preferably about 0.002 to 0.005 mm thick, and is preferably attached with a weather resistant adhesive, such as an acrylic adhesive.

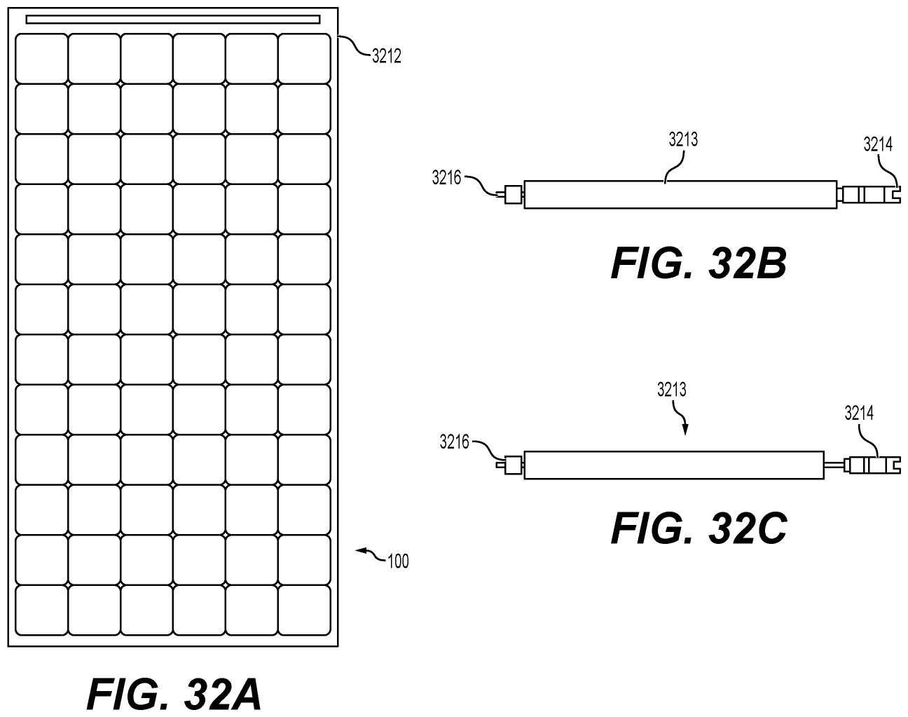

In the embodiment depicted in FIGS. 32a, 32b, and 32c, module level power electronics (MPLE) can be combined with the junction box to form a single electrical enclosure on each PV module 100. Junction boxes are preferably in the form of thin long enclosure 3212, with the power electrical parts securely mounted/fixed inside the enclosure. Preferably, connectors can be either fixed-length, like conventional junction box connectors shown in FIGS. 31a and 31b, or they can comprise a one-polarity connector 3214, with the other polarity being a build-in connector 3216. Furthermore, the one polarity cable 3214 can be retractable into the enclosure 3212 and extendable when needed to connect to the connector 3216 of an adjacent PV module 100. Either polarity connector can be fixed or retractable.

Preferably, the enclosure 3212 is substantially the same length as the module 100 width, to make the cable connections convenient. Additional wire trays and covers can thus be omitted, since only minimum lengths of cables are exposed to ambient wind/weather.

Various adhesion patterns for module mounting on shingles may be used. Prior adhesion patterns were, typically, 2×2, 3×3, or 4×4 arrays of uniformly-distributed strips of double stick tape. It has been found that such adhesion arrays provided less-than optimum adhesion of the modules top the roofs. Surprisingly, it has been determined that adhesion arrays that are more weighted to the outer edges of the modules act to more securely affix the modules to the roof surfaces. Adhesion patterns are designed to have module securely attached to composite shingle. Double sided thermoplastic adhesive tapes are preferable arranged for both portrait and landscape module installation orientation. Three preferable designs of the double side adhesive tape layout are described below. Adhesive tapes can be preinstalled on the module 100 in module factories.

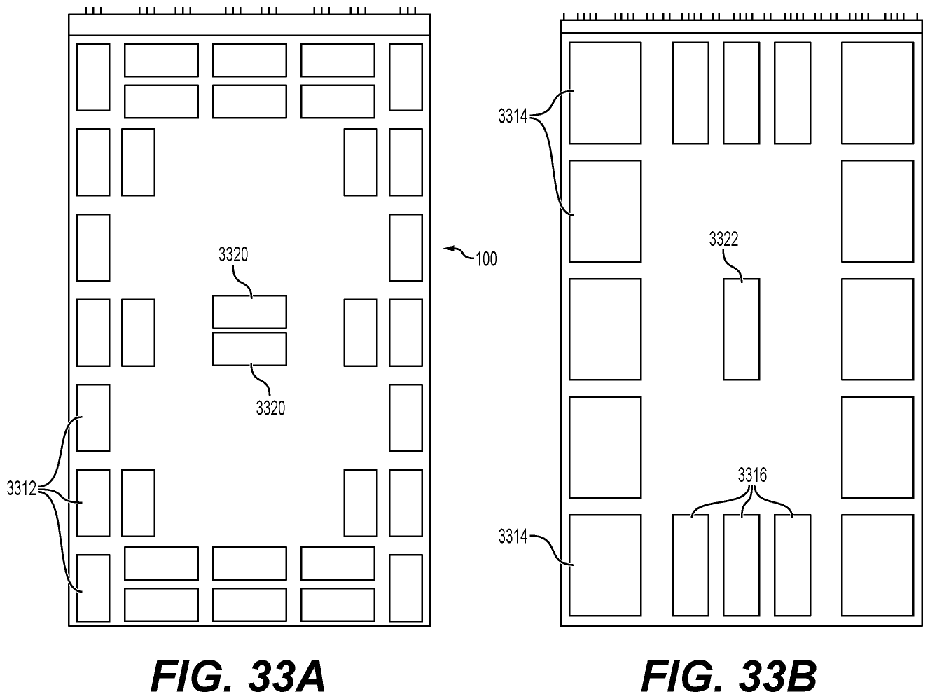

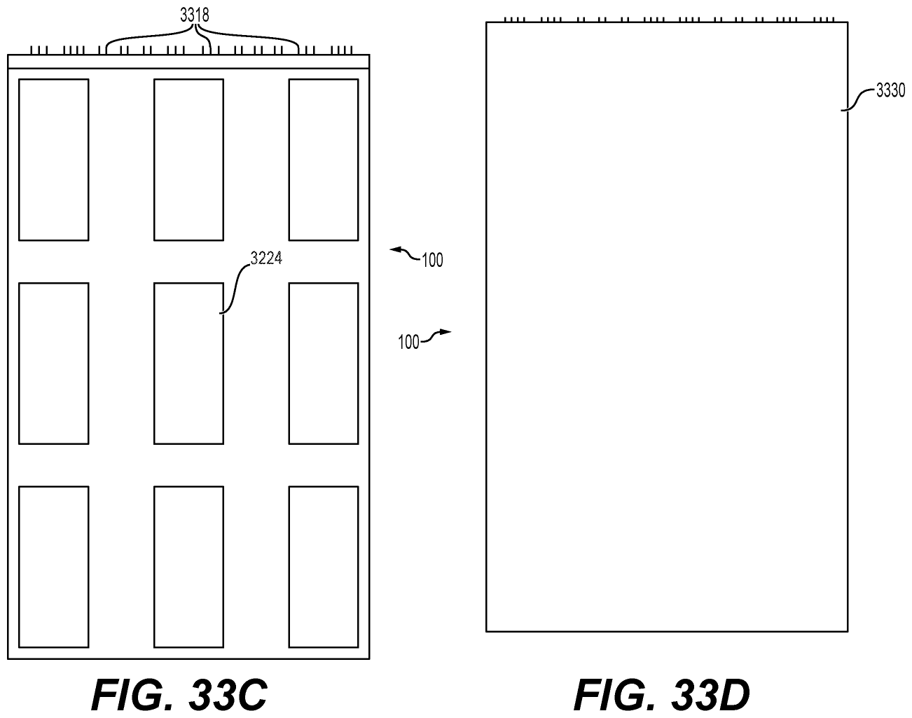

In FIG. 33a, the bottom surface of the module 100 (typically 4×8 feet) has a pattern of thirty-four adhesive portions 3312 distributed more toward the four edges of the module 100 that the inside portion thereof. Preferably, each adhesive pad is about 8 inches by 4 inches, which will thus cover approximately 42 percent of the bottom surface of the module 100. Preferably, the adhesive pad coverage should comprise between about 20 percent and about 70 percent of the module back surface, more preferably between about 30 percent and about 50 percent, and most preferably between about 40 percent and about 50 percent. Note the two center adhesion pads 3320, which will keep the center of the module 100 affixed to the roof surface, thus combating any wing foil lift which may be generated by the module 100 in high-wind conditions.

In FIG. 33b, the bottom surface of the module 100 is preferably covered with ten adhesive pads 3314 and seven adhesive pads 3316. The adhesive pads 3316 may be about 12 inches by 4 inches; and the adhesive pads 3314 may be about 12 inches by 8 inches (note that the pads 3314 may comprise two pads 3316 placed adjacent each other). Such an irregular two-dimensional array will provide about 48 percent coverage of the bottom surface of the module 100, thus providing greatly enhanced sticking power. Again, one or more center adhesive pads 3322 may be provided.

In FIG. 33c, nine to sixteen adhesive pads 3318 may be used. One or more center pads 3224 may also be provided. This configuration may result in about 44 percent coverage of the bottom surface of the module 100.

To protect double sided adhesive tapes before field installation, one or more removable protective film(s) 3330 is preferably applied on the double side adhesive tapes' outer surface on the bottom surface of the module 100, as shown in FIG. 33d. Such protective film(s) preferably should have low surface tension so it can be easily removed during module installation. Preferable materials for such film(s) can be, but are not limited to, wax paper, polyester film, fluoropolymer film, etc. One or two pieces of protective film 3330 can be applied on each module bottom surface.

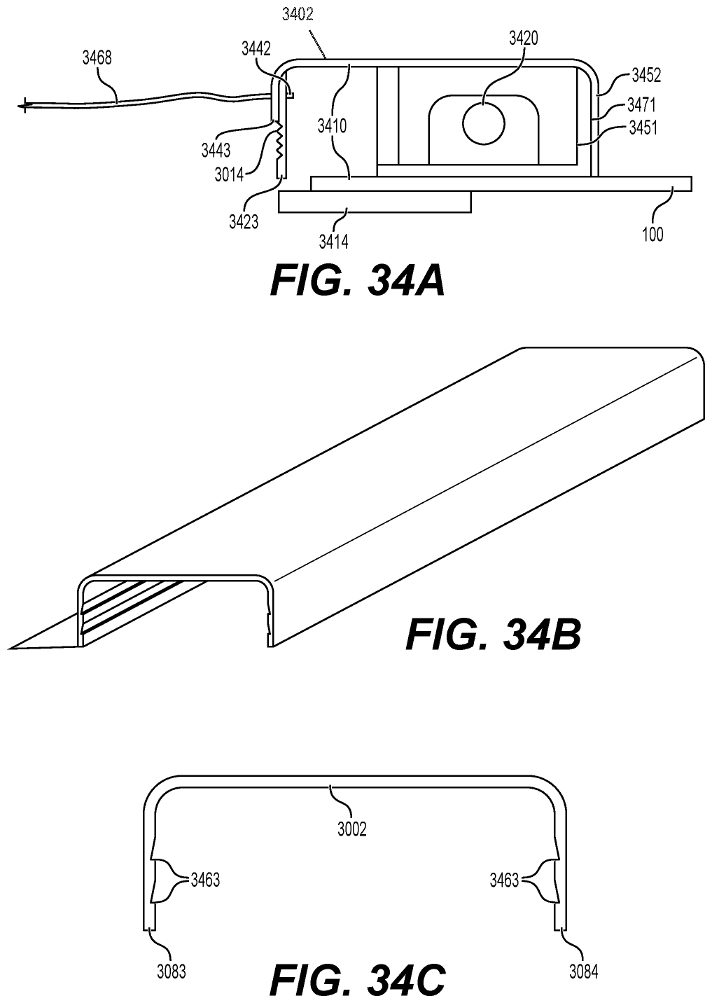

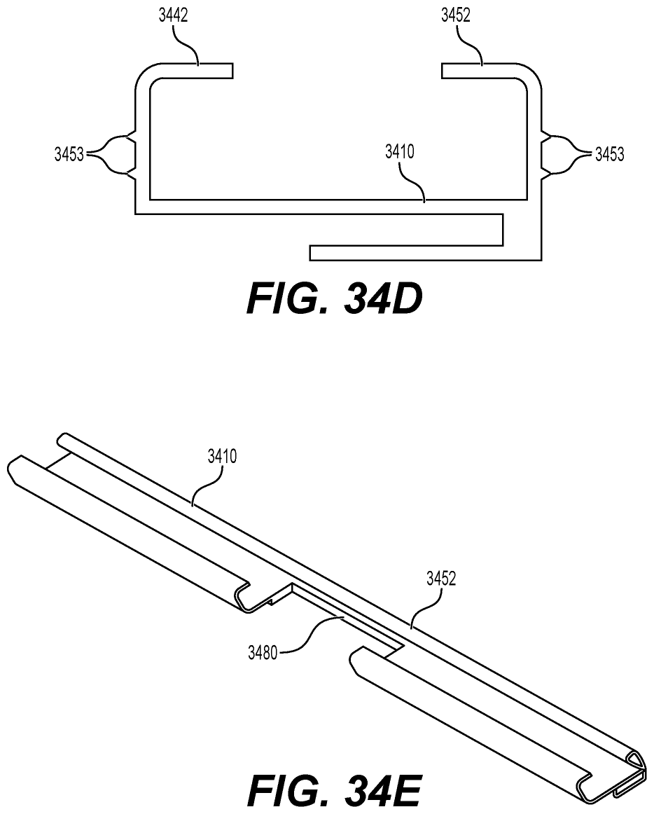

An alternative on-board tray and cover design is shown in FIGS. 34a, 34b, 34c, 34d, and 34e. The cross-section view of FIG. 34a shows the module 100 inserted into the gap 3412 between the base 3410 and the bottom shelf piece 3414. The module may be adhered to the base 3410 by glues, silicones, adhesives, screws, grommets, etc. The junction box 3420 is adhered to the base 3410 by adhesives, or other means described above. In the embodiment of FIG. 34a, the wire tray 3422 and top cover 3402 combine to form a rectangular cross-section, which provides a smaller footprint when viewed from above and from both orthogonal sides. The substantially rectangular cross section provides the lowest height tray and cover height.

As seen in FIGS. 34a, 34b, 34c, and 34d, the base portion 3410 has a substantially vertical left wall 3441 having a substantially horizontal wing portion 3442, and one, two, or more locking flanges 3443. The base portion 3410 also has a substantially vertical right wall 3451 having a substantially horizontal wing portion 3452, and one, two, or more locking flanges 3453. The cover portion 3402 has a substantially vertical left wall 3461, and one, two, or more locking flanges 3463; and a substantially vertical right wall 3471, and one, two, or more locking flanges 3473. When the cover is installed on the base, the locking flanges engage with each other to keep the cover installed, and the wing portions bias the cover upward, firmly engaging the locking flanges. Thus, the double clip structure on each side of the wire tray provides for the secure holding of the covers, and enhances the resistance to any wind uplift. This symmetrical cover design simplifies installation and reduces end cap numbers. The cover can be installed at either 0 degrees or 180 degrees, along the longitudinal axis, and the end caps can be used at either end.

As seen in FIG. 34e, the tray (or base) portion has a notch or a cutout portion 3480 configured to fit around the junction box 3420, and the integrated wings 3442 and 3452 are configured for holding the wire and connectors in place and biasing the cover upward to lock the locking flanges. Preferably, the tray (or base) portion 3410 is factory-installed on the module 100. Preferably, the cover has tapered ends 3483 and 3484 (FIG. 34c), where the cover can be removed with suitable tools, such as flat tip screw driver.

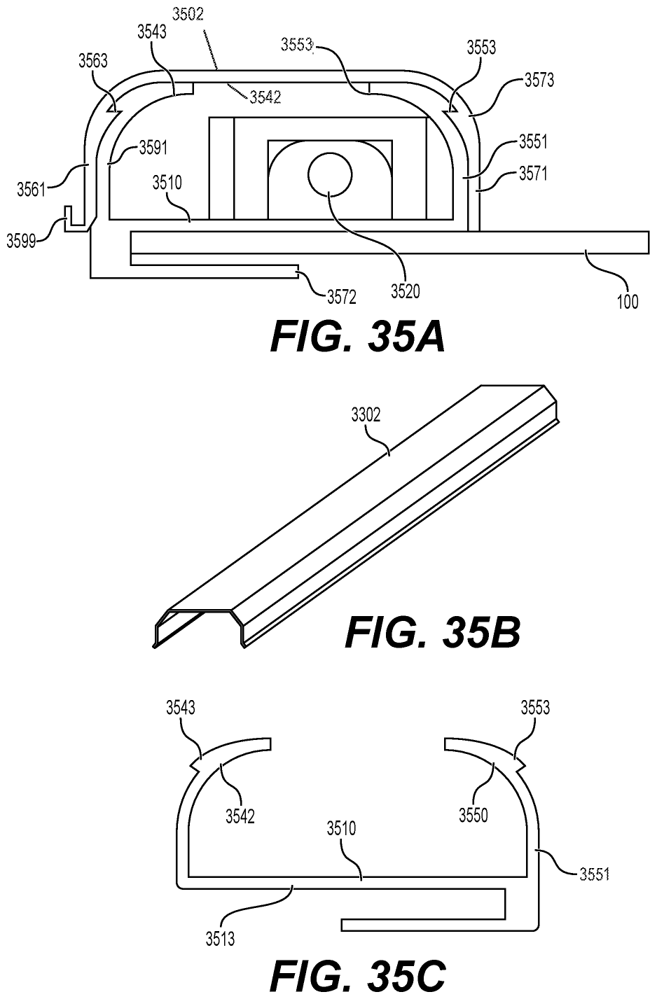

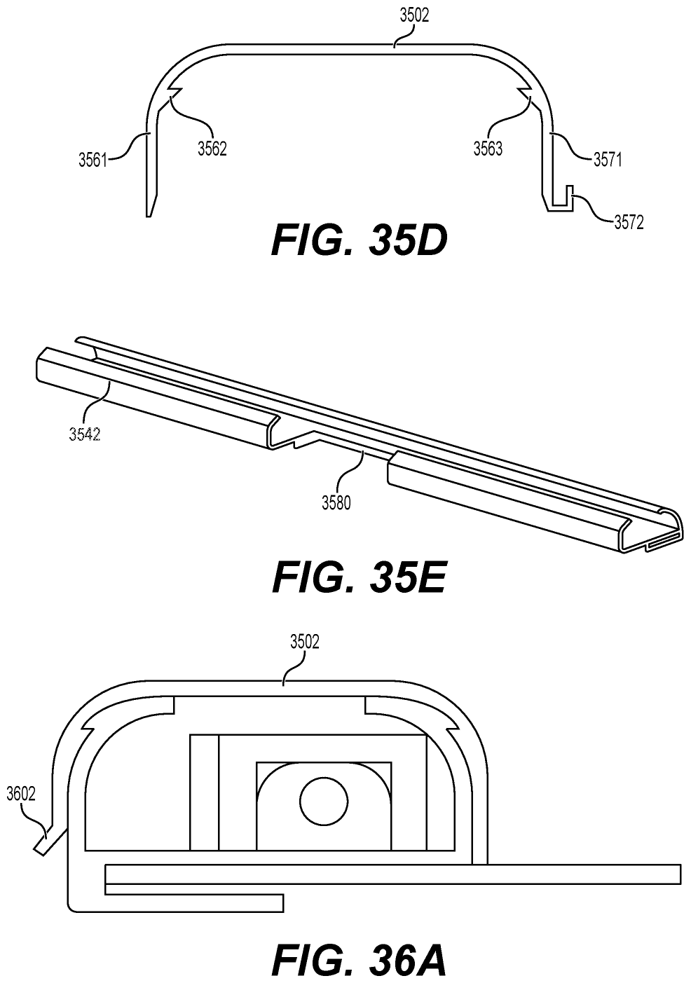

Another alternative embodiment is seen in FIGS. 35a, 35b, 35c, 35d, and 35e. The cross-section view of FIG. 35a shows the module 100 inserted into the gap 3512 between the base 3510 and the bottom shelf piece 3514. As seen in FIGS. 35a, 35b, 35c, and 35d, the base portion 3510 has a substantially vertical left wall 3541 sloping at a quarter curve into a substantially horizontal wing portion 3542, and one, two, or more locking flanges 3543. The base portion 3510 also has a substantially vertical right wall 3551 sloping at a quarter curve into a substantially horizontal wing portion 3552, and one, two, or more locking flanges 3553.

The cover portion 3502 has a substantially vertical left wall 3561, and one, two, or more locking flanges 3463; and a substantially vertical right wall 3571, and one, two, or more locking flanges 3573. When the cover is installed on the base, the locking flanges engage with each other to keep the cover installed, and the wing portions bias the cover upward, firmly engaging the locking flanges. Thus, the double clip structure on each side of the wire tray provides for the secure holding of the covers, and enhances the resistance to any wind uplift. This near symmetrical cover design simplifies installation and reduces end cap numbers. The end caps can be used at either end. The curved U-channel edge portion 3599 on the cover 3502 provides a tool access point to install or decouple the cover from the tray.

As seen in FIG. 35e, the tray (or base) portion 3502 has a notch or a cutout portion 3580 configured to fit around the junction box 3520, and the integrated wings 3542 and 3552 are configured for holding the wire and connectors in place and biasing the cover upward to lock the locking flanges. Preferably, the tray (or base) portion 3510 is factory-installed on the module 100. The FIGS. 35a-e embodiment presents a more curved, rounded appearance that the FIGS. 34a-e embodiment. This will aid in fending off wind and rain and snow and ice. Also, the more rounded wings 3542 and 3552 will provide an even stronger upward biasing force to more firmly engage the interlocking flanges.

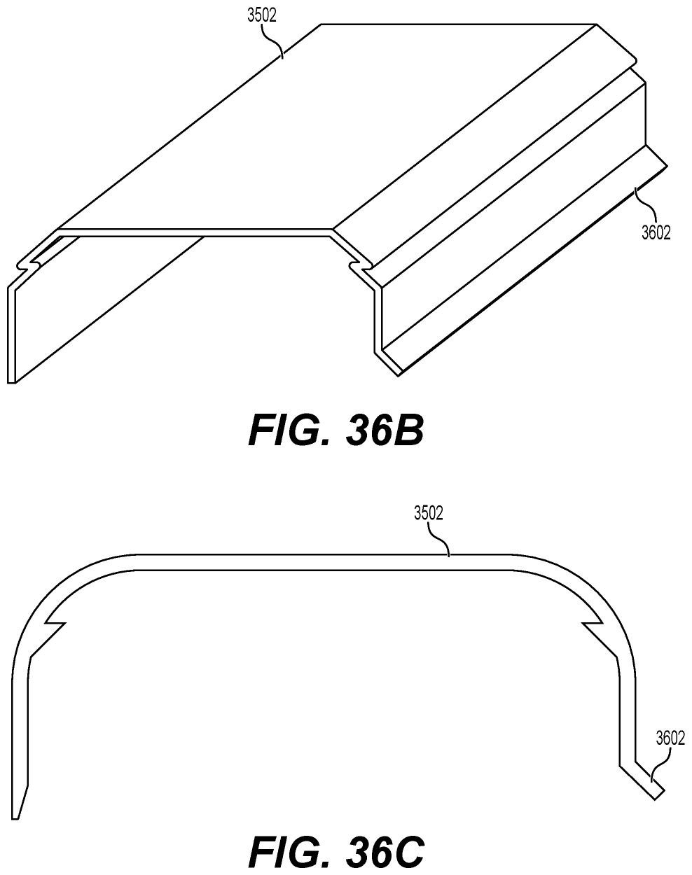

Yet another alternative embodiment is shown in FIGS. 36a, 36b, and 36c. The features are substantially the same as those shown in FIGS. 35a, 35b, and 35d, respectively, and will not be further described herein. However, the cover 3502 includes a bent edge 3602 which makes removal of the cover 3502 easy, with just one or more fingers.

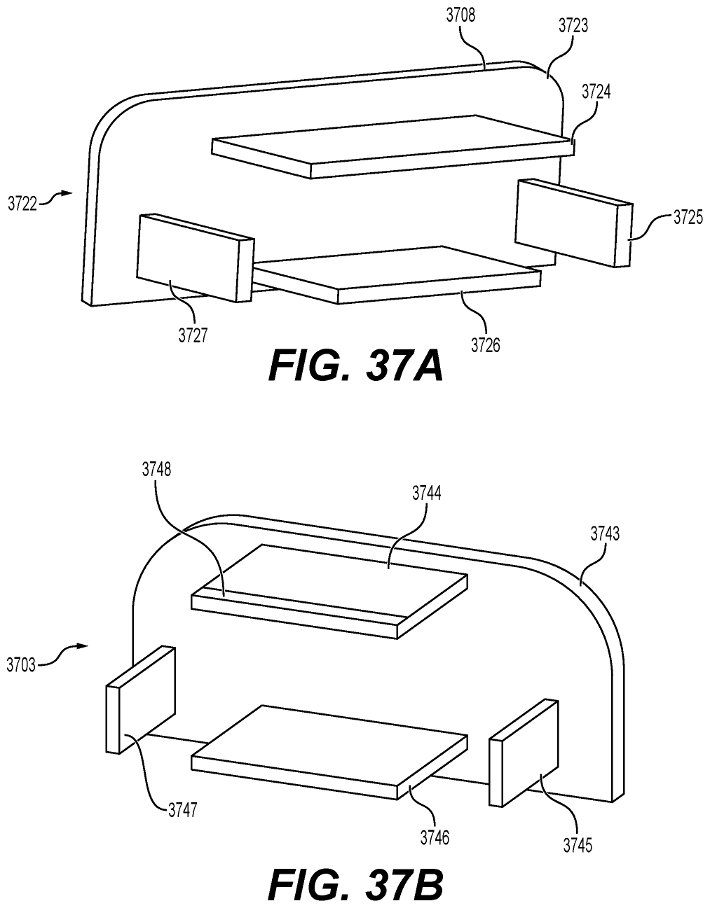

FIG. 37a shows an end cap for the embodiment of FIGS. 34a-e, while FIG. 37b shows an end cap for the embodiment of FIGS. 35a-e. In FIG. 37a, the end cap 3722 has a substantially flat end portion 3723 and four orthogonal projecting walls 3724, 3725, 3726, and 3727. The end portion 3723 preferably has a substantially rectangular profile, with radiused, curved corners at the upper edge thereof. Note that at least the projecting walls 3724 and 3726 have interlocking flanges 3728 and 3729 for interlocking-coupling with complementary interlocking flange structure on an adjacent cover. Of course, the projecting walls 3725 and 3727 may also have similar interlocking flanges. In FIG. 37b, the end cap 3742 has a substantially flat end portion 3743 and four orthogonal projecting walls 3744, 3745, 3746, and 3747. The end portion 3743 preferably has a substantially rectangular profile, with radiused, curved corners at the upper edge thereof, but the curve has a larger radius than the FIG. 37a embodiment. Note that at least the projecting walls 3744 and 3746 have interlocking flanges 3748 and 3749 for interlocking-coupling with complementary interlocking flange structure on an adjacent cover. Of course, the projecting walls 3745 and 3747 may also have similar interlocking flanges.

The present invention is disclosed herein in terms of a preferred embodiment thereof, which provides an exterior building module as defined in the appended claims. Various changes, modifications, and alterations in the teachings of the present invention may be contemplated by those skilled in the art without departing from the intended spirit and scope of the appended claims. It is intended that the present invention encompass such changes and modifications.

What is claimed is:

1. A photovoltaic module, comprising:
an upper transparent protective layer;
a photovoltaic layer positioned beneath the upper transparent protective layer, the photovoltaic layer comprising a plurality of electrically interconnected photovoltaic cells disposed in an array;
a substrate layer positioned beneath the photovoltaic layer;
a wire support tray assembly affixed to an edge of the photovoltaic module,
the wire support tray assembly comprising a base portion and a cover portion, the base portion having at least one base flange configured to lock with at least one corresponding cover portion flange;
the base portion having a longitudinally-extending slot configured to couple with said edge of the photovoltaic module,
a cross-section of the cover portion being substantially concave-shaped to protect the base portion from weather, and
the base portion comprising at least one biasing member configured to provide spring mechanism against the cover portion and configured to keep tension between the at least one base flange and the cover portion.

2. The photovoltaic module according to claim 1, wherein wire support tray assembly comprises a polymer material.

3. The photovoltaic module according to claim 1, wherein the base portion is coupled to the cover portion with a hinge portion.

4. The photovoltaic module according to claim 1, wherein the base portion and the cover portion each have two longitudinally-extending flanges configured to couple the cover portion to the base portion.

5. The photovoltaic module according to claim 1, wherein the cover portion and the base portion occlude all wiring inside the tray.

6. The photovoltaic module according to claim 1, further comprising a junction box disposed on the base portion and under the cover portion.

7. The photovoltaic module according to claim 1, further comprising a spacer portion, coupleable to the base portion, and configured to mate with an adjacent photovoltaic module.

8. The photovoltaic module according to claim 1, wherein said edge comprises a tapered edge.

9. The photovoltaic module according to claim 1, wherein the base portion comprises a base and a tray, said tray being configured to be installed within and coupleable to the base.

10. The photovoltaic module according to claim 1, further comprising an end cap portion configured to couple to an open end of the wire support tray assembly.

11. The photovoltaic module according to claim 1, wherein the wire support tray assembly is affixed to an entire length of the edge of the photovoltaic module.

12. The photovoltaic module according to claim 1, wherein another wire support tray assembly is affixed to another edge of the photovoltaic module.

13. The photovoltaic module according to claim 1, further comprising a L-joint cover portion configured to cover at least one base portion disposed along two orthogonal sides of a corner of the photovoltaic module.

14. The photovoltaic module according to claim 1, further comprising a T-joint cover portion configured to cover at least one base portion disposed at a T intersection along at least one edge of the photovoltaic module.

15. The photovoltaic module according to claim 1, wherein the at least one biasing member is further configured to retain a cable or wire disposed in a space between the base portion and the cover portion.

16. A photovoltaic module comprising:
a rectilinear panel having a surface with a plurality of photovoltaic cells disposed thereon in an array;
a wire tray assembly disposed along at least one edge of the photovoltaic module, the wire tray assembly comprising a base portion and a cover portion, the base portion and the cover portion being configured to provide a space between the base and cover portions to accommodate at least one cable connecting the photovoltaic cells, the cover portion having structure configured to removably couple the cover portion to the base portion, the wire tray assembly comprising polymer material, wherein a cross-section of the cover portion is substantially concave-shaped; and
at least one joint cover portion configured to cover adjacent base portions disposed at a junction of said adjacent base portions.

17. The photovoltaic module according to claim 16, wherein the cover portion is configured to prevent ingress of water to the base portion.

18. The photovoltaic module according to claim 16, wherein the base portion has structure configured to couple with a spacer portion, and wherein the spacer portion has structure to couple to an adjacent photovoltaic module.

19. The photovoltaic module according to claim 16, wherein the cover portion substantially concave-shaped cross section includes a flaring portion on one side of the cover portion.

20. The photovoltaic module according to claim 16, wherein the base portion includes at least on hole therein configured to provide transportation access.
